(19) United States
(12) Patent Application Publication
(10) Pub. No.: US 2025/0143147 A1
(43) Pub. Date: May 1, 2025

(54) DISPLAY DEVICE, METHOD OF FABRICATING THE SAME AND HEAD MOUNTED DISPLAY DEVICE INCLUDING THE SAME

(71) Applicant: Samsung Display Co., LTD., Yongin-si (KR)

(72) Inventors: Kyu Ho JUNG, Yongin-si (KR); Hyun Jin MAENG, Yongin-si (KR); Sang Chul BYUN, Yongin-si (KR); Jin Ho CHO, Yongin-si (KR); Soo Yeon HAN, Yongin-si (KR)

(21) Appl. No.: 18/933,678

(22) Filed: Oct. 31, 2024

(30) Foreign Application Priority Data
Nov. 1, 2023 (KR) 10-2023-0149151

(51) Int. Cl. H10K 59/80; H10K 59/131

(52) U.S. Cl. CPC H10K 59/8731; H10K 59/131; H10K 59/879

(57) ABSTRACT

A display device, method of fabricating the same and head mounted display device including the same are provided. The display device includes a semiconductor substrate including a display area including transistors, and a non-display area around the display area in plan view, a light-emitting element layer above the semiconductor substrate, and including light-emitting elements in the display area, an encapsulation layer above the light-emitting element layer, a color filter layer above the encapsulation layer, and including color filters respectively overlapping the light-emitting elements, a lens array layer above the color filter layer, and including lenses in the display area, and a cover layer above the lens array layer, having flat top and side surfaces, and surrounding the light-emitting element layer, the encapsulation layer, the color filter layer, and the lens array layer in plan view.

### CROSS-REFERENCE TO RELATED APPLICATION

The present application claims priority to, and the benefit of, Korean Patent Application No. 10-2023-0149151, filed on Nov. 1, 2023, in the Korean Intellectual Property Office, the entire disclosure of which is incorporated herein by reference.

### BACKGROUND

### 1. Field

The present disclosure relates to a display device, a method of fabricating the same, and a head mounted display device including the same.

### 2. Description of the Related Art

A head mounted display device (HMD) is an image display device that is worn on a user's head in the form of glasses or helmets to form a focus at a relatively close distance in front of the user's eyes. The head mounted display device may implement virtual reality (VR) or augmented reality (AR).

The head mounted display device magnifies an image displayed on a small display device by using a plurality of lenses, and displays the magnified image. Therefore, the display device applied to the head mounted display device needs to provide high-resolution images, for example, images with a resolution of 3000 PPI (Pixels Per Inch) or higher. To this end, an organic light-emitting diode on silicon (OLEDoS), which is a high-resolution small organic light-emitting display device, is used as the display device applied to the head mounted display device. The OLEDoS is an image display device in which an organic light-emitting diode (OLED) is located on a semiconductor wafer substrate on which a complementary metal oxide semiconductor (CMOS) is located.

### SUMMARY

Aspects of the present disclosure provide a display device including a cover layer containing a resin and having a smooth top surface without having an additional hard cover member, and a method of fabricating the same.

Aspects of the present disclosure also provide a head mounted display device including the display device.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to one or more embodiments of the disclosure, a display device includes a semiconductor substrate including a display area including transistors, and a non-display area around the display area in plan view, a light-emitting element layer above the semiconductor substrate, and including light-emitting elements in the display area, an encapsulation layer above the light-emitting element layer, a color filter layer above the encapsulation layer, and including color filters respectively overlapping the light-emitting elements, a lens array layer above the color filter layer, and including lenses in the display area, and a cover layer above the lens array layer, having flat top and side surfaces, and surrounding the light-emitting element layer, the encapsulation layer, the color filter layer, and the lens array layer in plan view.

The display device may further include pads in the non-display area, wherein the cover layer does not overlap the pads.

The display device may further include a sealing dam in the non-display area, and surrounding the cover layer in plan view, wherein a planar area of a region surrounded by the sealing dam is equal to a planar area of the cover layer.

The sealing dam may contact a side surface of the cover layer, wherein a height of the sealing dam is equal to a height of the cover layer.

The display device may further include a gate driver and a scan driver in the non-display area, wherein the sealing dam surrounds the gate driver and the scan driver in plan view, and wherein the cover layer overlaps the gate driver and the scan driver.

The sealing dam and the cover layer may include a polymer resin.

The encapsulation layer may include a first inorganic encapsulation layer, an organic encapsulation layer above the first inorganic encapsulation layer, and a second inorganic encapsulation layer above the organic encapsulation layer, wherein the cover layer overlaps an inorganic junction area where the first inorganic encapsulation layer and the second inorganic encapsulation layer contact each other in the non-display area.

The cover layer may directly contact the lenses of the lens array layer.

According to one or more embodiments of the disclosure, a method of fabricating a display device includes preparing a wafer substrate including transistors, and having unit areas defined therein, forming light-emitting element layers including light-emitting elements in the unit areas of the wafer substrate, forming an encapsulation layer above the light-emitting element layer, forming a color filter layer above the encapsulation layer, forming a lens array layer above the color filter layer, applying a resin layer on the lens array layer, planarizing a top surface of the resin layer, curing the resin layer to form a cover layer surrounding the light-emitting element layer, the encapsulation layer, the color filter layer, and the lens array layer in plan view, and splitting the wafer substrate into the unit areas to form display panels.

The method may further include forming a sealing dam surrounding the light-emitting element layer for the unit areas of the wafer substrate, wherein the resin layer is applied within a region surrounding the sealing dam.

The planarizing of the top surface of the resin layer may include attaching a release film having a flat bottom surface onto the sealing dam and the resin layer, wherein the resin layer fills a space defined by the sealing dam and the release film.

In the attaching of the release film, the resin layer may surround the light-emitting element layer, the encapsulation layer, the color filter layer, and the lens array layer within the unit area of the wafer substrate in plan view.

The cover layer may include a flat top surface and a side surface directly contacting the sealing dam.

The planarizing of the top surface of the resin layer includes placing a mold including a recessed portion corresponding to the unit area where the light-emitting element layer is located, wherein the resin layer fills a space defined by the wafer substrate and the mold.

A depth of the recessed portion of the mold may be equal to a thickness of the cover layer.

The mold may include a transparent material.

The method may further include placing a mask including holes respectively corresponding to the unit areas on the wafer substrate, wherein the planarizing of the top surface of the resin layer includes placing a mold on the mask, and wherein the resin layer fills a space defined by the wafer substrate, the mask, and the mold.

The resin layer may surround the light-emitting element layer, the encapsulation layer, the color filter layer, and the lens array layer.

A thickness of the mask may be greater than a height of the lens array layer, wherein the mold has a bottom surface having protrusions respectively corresponding to the holes of the mask, and wherein a thickness of the protrusion of the mold is less than the thickness of the mask.

The mask may include a metal material, wherein the mold includes a flexible material.

The mask may include a flexible material, wherein the mold is a transparent hard mold.

The method may further include placing a soft mask defining holes respectively corresponding to the unit areas on the wafer substrate, wherein the planarizing of the top surface of the resin layer includes placing a release film having a flat bottom surface on the soft mask, and wherein the resin layer fills a space defined by the wafer substrate, the soft mask, and the release film.

A thickness of the soft mask may be substantially equal to a thickness of the cover layer.

According to one or more embodiments of the disclosure, a head mounted display device includes a frame mounted on a user's body, and corresponding to left and right eyes, display devices in the frame, and an eyepiece above the display devices, wherein the display devices include a semiconductor substrate including a display area including transistors, and a non-display area around the display area in plan view, a light-emitting element layer above the semiconductor substrate, and including light-emitting elements in the display area, an encapsulation layer above the light-emitting element layer, a color filter layer above the encapsulation layer, and including color filters respectively overlapping the light-emitting elements, a lens array layer above the color filter layer, and including lenses in the display area, and a cover layer above the lens array layer, having flat top and side surfaces, and surrounding the light-emitting element layer, the encapsulation layer, the color filter layer, and the lens array layer in plan view.

The display device may further include a sealing dam in the non-display area, and surrounding the cover layer in plan view, wherein the sealing dam directly contacts a side surface of the cover layer.

A method of fabricating a display device according to one or more embodiments may include planarizing a top surface and a side surface of a resin layer applied on a light-emitting element layer on a wafer substrate, and curing the resin layer to form a cover layer. The display device may include the cover layer having a smooth top surface capable of protecting a display panel without a separate hard cover member.

The display device according to one or more embodiments may reduce or prevent damage to a hard cover member during a fabrication process, and may have smooth surface quality by including the cover layer made of a transparent resin.

However, aspects according to the embodiments of the present disclosure are not limited to those exemplified above, and various other aspects are incorporated herein.

### BRIEF DESCRIPTION OF THE DRAWINGS

The above and other aspects of the present disclosure will become more apparent by describing in detail embodiments thereof with reference to the attached drawings, in which:

FIG. 1 is an exploded perspective view of a display device according to one or more embodiments;

FIG. 2 is a block diagram illustrating a display device according to one or more embodiments;

FIG. 3 is an equivalent circuit diagram of a sub-pixel according to one or more embodiments;

FIG. 4 is a diagram showing a display panel according to one or more embodiments;

FIG. 5 is a view illustrating a layout of a sealing dam and a cover layer located in a display panel according to one or more embodiments;

FIG. 6 is a plan view showing first electrodes and emission areas of a plurality of pixels located in a display area of FIG. 4, and a pixel-defining layer;

FIG. 7 is a plan view showing first electrodes and emission areas of a plurality of sub-pixels, and a pixel-defining layer according to one or more other embodiments;

FIG. 8 is a schematic cross-sectional view taken along the line A-A′ of FIG. 6;

FIG. 9 is an enlarged view showing area X of FIG. 4;

FIG. 10 is a schematic cross-sectional view taken along the line B-B′ of FIG. 9;

FIG. 11 is an enlarged view showing area Y of FIG. 4;

FIG. 12 is a schematic cross-sectional view taken along the line C-C′ of FIG. 11;

FIG. 13 is a schematic cross-sectional view of a display panel along a second direction according to one or more embodiments;

FIGS. 14 to 24 are diagrams sequentially showing a fabrication process of a display device according to one or more embodiments;

FIG. 25 is a schematic cross-sectional view of a display panel of a display device along a second direction according to one or more other embodiments;

FIGS. 26 to 31 are cross-sectional views illustrating a part of a fabrication process of a display device according to one or more other embodiments;

FIGS. 32 to 36 are cross-sectional views illustrating a part of a fabrication process of a display device according to still one or more other embodiments;

FIG. 37 is a cross-sectional view illustrating one operation in a fabrication process of a display device according to yet one or more other embodiments;

FIGS. 38 to 41 are cross-sectional views illustrating a part of a fabrication process of a display device according to still one or more other embodiments;

FIG. 42 is a perspective view illustrating a head mounted display device according to one or more embodiments;

FIG. 43 is an exploded perspective view showing an example of the head mounted display device of FIG. 42; and

FIG. 44 is a perspective view illustrating a head mounted display device according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

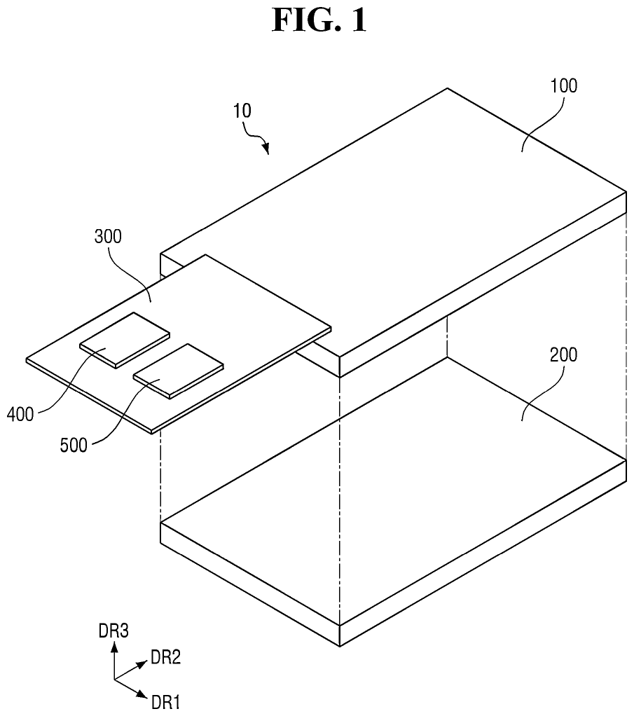

FIG. 1 is an exploded perspective view of a display device according to one or more embodiments.

Referring to FIG. 1, a display device 10 according to one or more embodiments is a device displaying a moving image or a still image. The display device 10 according to one or more embodiments may be applied to portable electronic devices such as a mobile phone, a smartphone, a tablet personal computer, a mobile communication terminal, an electronic organizer, an electronic book, a portable multimedia player (PMP), a navigation system, an ultra-mobile PC (UMPC) or the like. For example, the display device 10 may be applied as a display unit of a television, a laptop, a monitor, a billboard, or an Internet-of-Things (IoT) device. Alternatively, the display device 10 may be applied to a smart watch, a watch phone, a head mounted display device (HMD) for implementing virtual reality and augmented reality, and the like.

The display device 10 according to one or more embodiments includes a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape, having a short side of a first direction DR1, and a long side of a second direction DR2 crossing the first direction DR1. In the display panel 100, a corner where a short side in the first direction DR1 and a long side in the second direction DR2 meet may be right-angled or rounded with a curvature (e.g., predetermined curvature). The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but is not limited thereto.

The heat dissipation layer 200 may overlap the display panel 100 in a third direction DR3, which is the thickness direction of the display panel 100. The heat dissipation layer 200 may be located on one surface of the display panel 100, for example, on the rear surface thereof. The heat dissipation layer 200 serves to dissipate heat generated from the display panel 100. The heat dissipation layer 200 may include graphite or a metal layer having high thermal conductivity, such as silver (Ag), copper (Cu), or aluminum (Al).

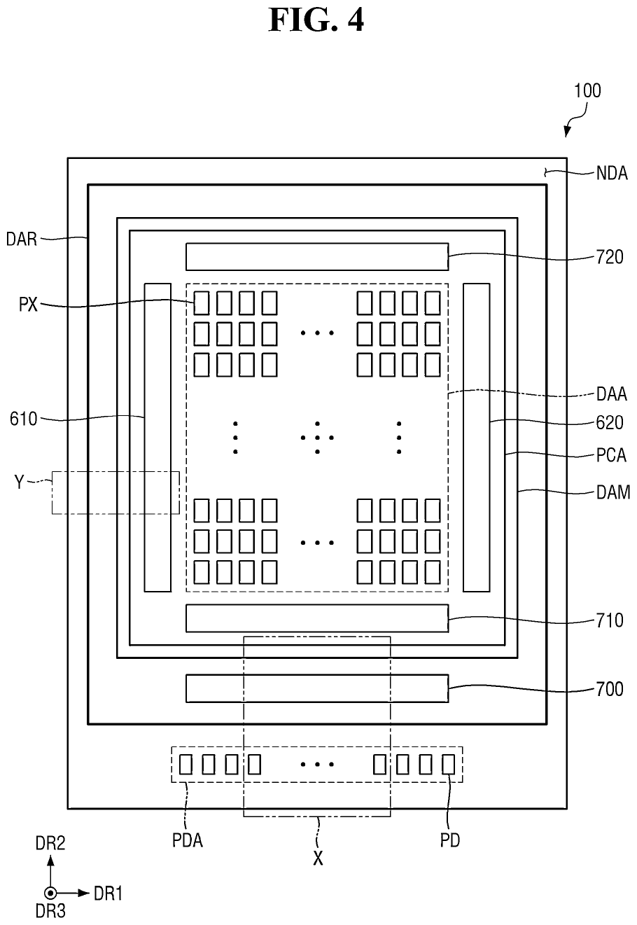

The circuit board 300 may be electrically connected to a plurality of pads PD (see FIG. 4) of a pad portion PDA (see FIG. 4) of the display panel 100 by using a conductive adhesive member such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. In this case, one end of the circuit board 300 may be located on the rear surface of the display panel 100 and/or the rear surface of the heat dissipation layer 200. One end of the circuit board 300 may be an opposite end of the other end of the circuit board 300 connected to the plurality of pads PD (see FIG. 4) of the pad portion PDA (see FIG. 4) of the display panel 100 by using a conductive adhesive member.

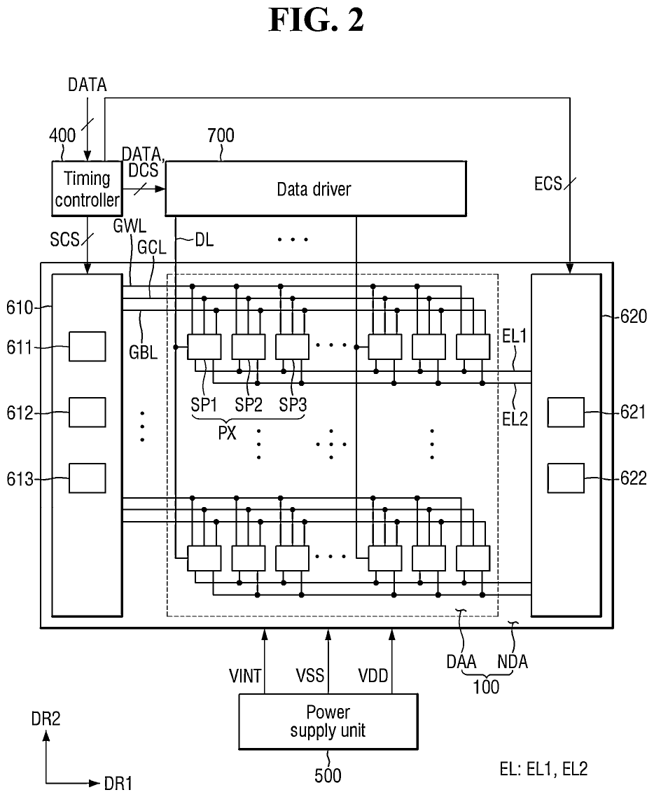

The timing control circuit 400 may receive digital video data and timing signals inputted from the outside. The timing control circuit 400 may generate a scan-timing control signal SCS (see FIG. 2), an emission-timing control signal ECS (see FIG. 2), and a data-timing control signal DCS (see FIG. 2) for controlling the display panel 100 in response to the timing signals. The timing control circuit 400 may output the scan-timing control signal SCS to a scan driver 610 (see FIG. 2), and may output the emission-timing control signal ECS to an emission driver 620 (see FIG. 2). The timing control circuit 400 may output the digital video data and the data-timing control signal DCS to a data driver 700 (see FIG. 2).

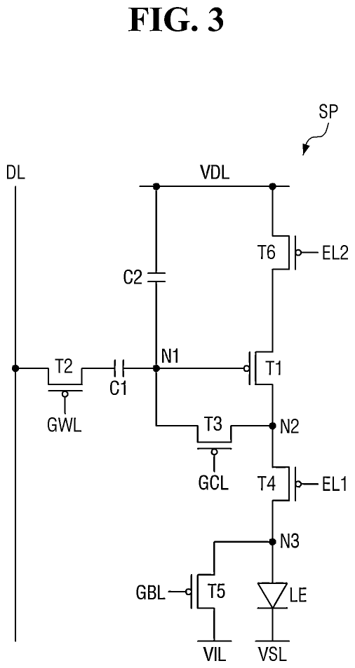

The power supply circuit 500 may generate a plurality of panel-driving voltages according to a power voltage from the outside. For example, the power supply circuit 500 may generate a first driving voltage VSS (see FIG. 2), a second driving voltage VDD (see FIG. 2), and a third driving voltage VINT (see FIG. 2), and may supply the voltages to the display panel 100. The first driving voltage VSS, the second driving voltage VDD, and the third driving voltage VINT will be described later in conjunction with FIG. 3.

Each of the timing control circuit 400 and the power supply circuit 500 may be formed as an integrated circuit (IC), and may be attached to one surface of the circuit board 300. In this case, the scan-timing control signal SCS, the emission-timing control signal ECS, digital video data DATA (see FIG. 2), and the data-timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

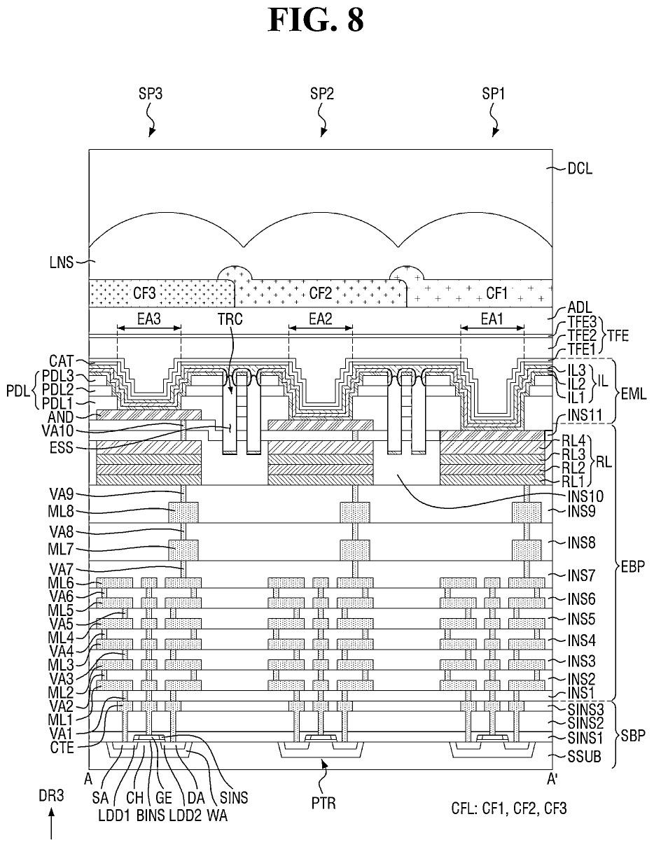

Alternatively, each of the timing control circuit 400 and the power supply circuit 500 may be located in a non-display area NDA (see FIG. 2) of the display panel 100, similarly to the scan driver 610, the emission driver 620, and the data driver 700. In this case, the timing control circuit 400 may include a plurality of timing transistors, and each of the power supply circuits 500 may include a plurality of power transistors. The plurality of timing transistors and the plurality of power transistors may be formed on a semiconductor substrate SSUB (see FIG. 8) through a semiconductor process. For example, the plurality of timing transistors and the plurality of power transistors may be formed of CMOS. Each of the timing control circuit 400 and the power supply circuit 500 may be located between the data driver 700 and the pad portion PDA (see FIG. 4).

FIG. 2 is a block diagram illustrating a display device according to one or more embodiments.

Referring to FIG. 2, the display panel 100 may include a display area DAA and the non-display area NDA located around the display area DAA. In the display area DAA, a plurality of pixels PX are located to emit light or display an image. In the non-display area NDA, light may not be emitted, or an image may not be displayed.

The display panel 100 may include the plurality of pixels PX, a plurality of scan lines, a plurality of emission control lines EL (e.g., EL1 and EL2), and a plurality of data lines DL that are located in the display area DAA.

The plurality of pixels PX may be arranged in the first and second directions DR1 and DR2. The plurality of pixels PX may be arranged in a matrix in the display area DAA. The plurality of scan lines and the plurality of emission control lines EL may extend in the first direction DR1, and may be arranged to be spaced apart in the second direction DR2. The plurality of data lines DL may extend in the second direction DR2, and may be arranged to be spaced apart in the first direction DR1.

The plurality of scan lines may include a plurality of write scan lines GWL, a plurality of control scan lines GCL, and a plurality of bias scan lines GBL. The plurality of emission control lines EL include a plurality of first emission control lines EL1 and a plurality of second emission control lines EL2.

The plurality of pixels PX may include a plurality of sub-pixels SP1, SP2, and SP3. The plurality of sub-pixels SP1, SP2, and SP3 may include a plurality of pixel transistors as shown in FIG. 3. The plurality of pixel transistors may be formed through a semiconductor process to be located on the semiconductor substrate SSUB (see FIG. 8). For example, the plurality of pixel transistors may be formed of complementary metal oxide semiconductor (CMOS).

Each of the plurality of sub-pixels SP1, SP2, and SP3 may be connected to any one write scan line GWL among the plurality of write scan lines GWL, any one control scan line GCL among the plurality of control scan lines GCL, any one bias scan line GBL among the plurality of bias scan lines GBL, any one first emission control line EL1 among the plurality of first emission control lines EL1, any one second emission control line EL2 among the plurality of second emission control lines EL2, and/or any one data line DL among the plurality of data lines DL. Each of the plurality of sub-pixels SP1, SP2, and SP3 may receive a data voltage of the data line DL in response to a write scan signal of the write scan line GWL, and emit light from the light-emitting element according to the data voltage.

The display panel 100 may include the scan driver 610, the emission driver 620, and the data driver 700 that are located in the non-display area NDA.

The scan driver 610 includes a plurality of scan transistors, and the emission driver 620 includes a plurality of light-emitting transistors. The plurality of scan transistors and the plurality of light-emitting transistors may be formed on the semiconductor substrate SSUB (see FIG. 8) through a semiconductor process. For example, the plurality of scan transistors and the plurality of light-emitting transistors may be formed of CMOS. Although it is illustrated in FIG. 2 that the scan driver 610 is located on the left side of the display area DAA and the emission driver 620 is located on the right side of the display area DAA, the present disclosure is not limited thereto. For example, the scan driver 610 and the emission driver 620 may be located on both the left side and the right side of the display area DAA.

The scan driver 610 may include a write scan signal output part 611, a control scan signal output part 612, and a bias scan signal output part 613. Each of the write scan signal output part 611, the control scan signal output part 612, and the bias scan signal output part 613 may receive the scan-timing control signal SCS from the timing control circuit 400. The write scan signal output part 611 may generate write scan signals according to the scan-timing control signal SCS of the timing control circuit 400, and may output them sequentially to the write scan lines GWL. The control scan signal output part 612 may generate control scan signals in response to the scan-timing control signal SCS and sequentially output them to the control scan lines GCL. The bias scan signal output part 613 may generate bias scan signals according to the scan-timing control signal SCS, and may output them sequentially to the bias scan lines GBL.

The emission driver 620 includes a first emission control driver 621 and a second emission control driver 622. Each of the first emission control driver 621 and the second emission control driver 622 may receive the emission-timing control signal ECS from the timing control circuit 400. The first emission control driver 621 may generate first emission control signals according to the emission-timing control signal ECS and sequentially output them to the first emission control lines EL1. The second emission control driver 622 may generate second emission control signals according to the emission-timing control signal ECS and sequentially output them to the second emission control lines EL2.

The data driver 700 may include a plurality of data transistors, and the plurality of data transistors may be formed on the semiconductor substrate SSUB (see FIG. 8) through a semiconductor process. For example, the plurality of data transistors may be formed of CMOS.

The data driver 700 may receive the digital video data DATA and the data-timing control signal DCS from the timing control circuit 400. The data driver 700 converts the digital video data DATA into analog data voltages according to the data-timing control signal DCS, and outputs the analog data voltages to the data lines DL. In this case, the sub-pixels SP1, SP2, and SP3 are selected by the write scan signal of the scan driver 610, and data voltages may be supplied to the selected sub-pixels SP1, SP2, and SP3.

FIG. 3 is an equivalent circuit diagram of a sub-pixel according to one or more embodiments.

Referring to FIG. 3, the sub-pixel SP may be connected to the write scan line GWL, the control scan line GCL, the bias scan line GBL, the first emission control line EL1, the second emission control line EL2, and the data line DL. In addition, the sub-pixel SP may be connected to a first driving voltage line VSL to which the first driving voltage VSS (see FIG. 2) corresponding to a low potential voltage is applied, a second driving voltage line VDL to which the second driving voltage VDD (see FIG. 2) corresponding to a high potential voltage is applied, and a third driving voltage line VIL to which the third driving voltage VINT (see FIG. 2) corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be lower than the third driving voltage VINT. The second driving voltage VDD may be higher than the third driving voltage VINT.

The sub-pixel SP includes a plurality of transistors T1, T2, T3, T4, T5, and T6, a light-emitting element LE, a first capacitor C1, and a second capacitor C2.

The light-emitting element LE emits light in response to a driving current Ids flowing through the channel of the first transistor T1. The emission amount of the light-emitting element LE may be proportional to the driving current Ids. The light-emitting element LE may be located between the fourth transistor T4 and the first driving voltage line VSL. The first electrode of the light-emitting element LE may be connected to the drain electrode of the fourth transistor T4, and the second electrode thereof may be connected to the first driving voltage line VSL. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer located between the first electrode and the second electrode, but is not limited thereto. For example, the light-emitting element LE may be an inorganic light-emitting element including a first electrode, a second electrode, and an inorganic semiconductor located between the first electrode and the second electrode, in which case the light-emitting element LE may be a micro light-emitting diode.

The first transistor T1 may be a driving transistor that controls a source-drain current (hereinafter referred to as a “driving current”) flowing between the source electrode and the drain electrode thereof according to a voltage applied to the gate electrode thereof. The first transistor T1 includes a gate electrode connected to the first node N1, a source electrode connected to the drain electrode of the sixth transistor T6, and a drain electrode connected to a second node N2.

The second transistor T2 may be located between one electrode of the first capacitor C1 and the data line DL. The second transistor T2 is turned on by the write scan signal of the write scan line GWL to connect the one electrode of the first capacitor C1 to the data line DL. Accordingly, the data voltage of the data line DL may be applied to the one electrode of the first capacitor C1. The second transistor T2 includes a gate electrode connected to the write scan line GWL, a source electrode connected to the data line DL, and a drain electrode connected to the one electrode of the first capacitor C1.

The third transistor T3 may be located between the first node N1 and the second node N2. The third transistor T3 is turned on by the control scan signal of the control scan line GCL to connect the first node N1 to the second node N2. For this reason, because the gate electrode and the source electrode of the first transistor T1 are connected, the first transistor T1 may operate like a diode. The third transistor T3 includes a gate electrode connected to the control scan line GCL, a source electrode connected to the second node N2, and a drain electrode connected to the first node N1.

The fourth transistor T4 may be connected between the second node N2 and a third node N3. The fourth transistor T4 is turned on by the first emission control signal of the first emission control line EL1 to connect the second node N2 to the third node N3. Accordingly, the driving current of the first transistor T1 may be supplied to the light-emitting element LE. The fourth transistor T4 includes a gate electrode connected to the first emission control line EL1, a source electrode connected to the second node N2, and a drain electrode connected to the third node N3.

The fifth transistor T5 may be located between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light-emitting element LE. The fifth transistor T5 includes a gate electrode connected to the bias scan line GBL, a source electrode connected to the third node N3, and a drain electrode connected to the third driving voltage line VIL.

The sixth transistor T6 may be located between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and a drain electrode connected to the source electrode of the first transistor T1.

The first capacitor C1 is formed between the first node N1 and the drain electrode of the second transistor T2. The first capacitor C1 includes one electrode connected to the drain electrode of the second transistor T2 and the other electrode connected to the first node N1.

The second capacitor C2 is formed between the gate electrode of the first transistor T1 and the second driving voltage line VDL. The second capacitor C2 includes one electrode connected to the gate electrode of the first transistor T1 and the other electrode connected to the second driving voltage line VDL.

The first node N1 is a junction between the gate electrode of the first transistor T1, the drain electrode of the third transistor T3, the other electrode of the first capacitor C1, and the one electrode of the second capacitor C2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light-emitting element LE.

Each of the first to sixth transistors T1, T2, T3, T4, T5, and T6 may be a metal-oxide-semiconductor field effect transistor (MOSFET). For example, each of the first to sixth transistors T1, T2, T3, T4, T5, and T6 may be a P-type MOSFET, but is not limited thereto. Each of the first to sixth transistors T1, T2, T3, T4, T5, and T6 may be an N-type MOSFET. Alternatively, some of the first to sixth transistors T1, T2, T3, T4, T5, and T6 may be P-type MOSFETs, and each of the remaining transistors may be an N-type MOSFET.

Although FIG. 3 illustrates that the sub-pixel SP includes the six transistors T1, T2, T3, T4, T5, and T6 and the two capacitors C1 and C2, it should be noted that the equivalent circuit diagram of the sub-pixel SP is not limited to that shown in FIG. 3. For example, the number of the transistors and the number of the capacitors of the sub-pixel SP are not limited to the example shown in FIG. 3.

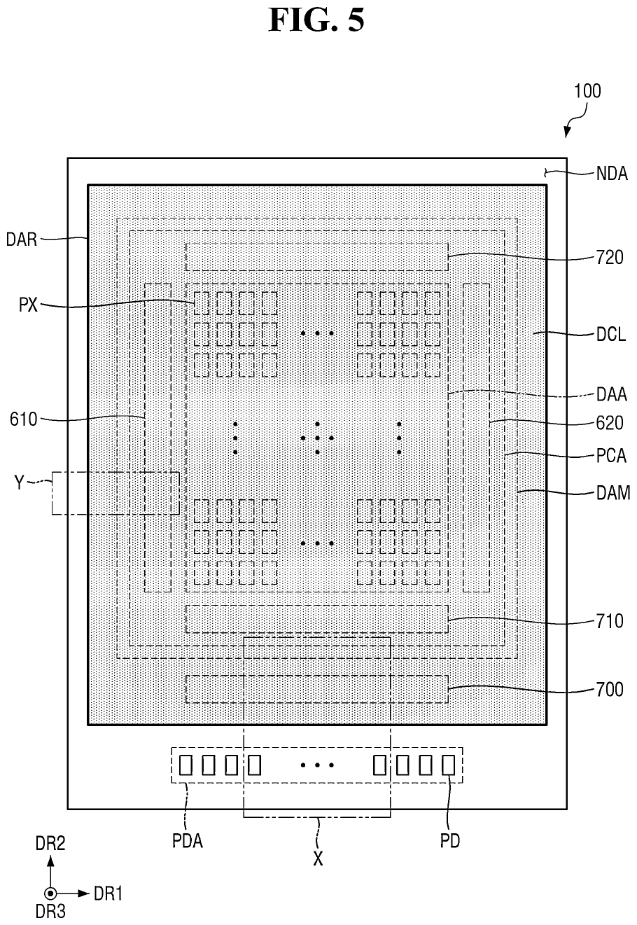

FIG. 4 is a diagram showing a display panel according to one or more embodiments. FIG. 5 is a view illustrating a layout of a sealing dam and a cover layer located in a display panel according to one or more embodiments. FIG. 5 shows a layout of a sealing dam DAR and a cover layer DCL in the display panel 100 of FIG. 4.

Referring to FIGS. 4 and 5, the display panel 100 according to one or more embodiments may include the plurality of pixels PX arranged in a matrix form in the display area DAA. The display panel 100 may include the scan driver 610, the emission driver 620, the data driver 700, a first distribution circuit 710, a second distribution circuit 720, the pad portion PDA, a power connection portion PCA, a dam DAM, and the sealing dam DAR that are located in the non-display area NDA. In addition, the display panel 100 may further include a static electricity protection portion, a moisture permeation reduction portion (e.g., a permeation prevention portion), and a crack reduction portion (e.g., a crack prevention portion) that are placed between the dam DAM and the sealing dam DAR, in one or more embodiments.

The scan driver 610 may be located on the first side of the display area DAA, and the emission driver 620 may be located on the second side of the display area DAA. For example, the scan driver 610 may be located on one side of the display area DAA in the first direction DR1, and the emission driver 620 may be located on the other side of the display area DAA in the first direction DR1. That is, the scan driver 610 may be located on the left side of the display area DAA, and the emission driver 620 may be located on the right side of the display area DAA. However, the present specification is not limited thereto, and the scan driver 610 and the emission driver 620 may be located on both the first side and the second side of the display area DAA.

The pad portion PDA may include the plurality of pads PD connected to pads or bumps of the circuit board 300 through a conductive adhesive member. The pad portion PDA may be located on the third side of the display area DAA. For example, the pad portion PDA may be located on one side of the display area DAA in the second direction DR2. That is, the pad portion PDA may be located on the lower side of the display area DAA. The pad portion PDA may be located outside the data driver 700 in the second direction DR2 (as used herein, “outside” may mean “outside in plan view”). That is, the pad portion PDA may be located closer to the edge of the display panel 100 than the data driver 700.

In one or more embodiments, the display panel 100 may further include inspection pads to check whether the display panel 100 operates normally. The inspection pads may be connected to a jig or a probe pin during an inspection process, or may be connected to a circuit board for inspection. The circuit board for inspection may be a printed circuit board made of a rigid material or a flexible printed circuit board made of a flexible material.

The first distribution circuit 710 distributes data voltages applied through the pad portion PDA to the plurality of data lines DL. For example, the first distribution circuit 710 may distribute the data voltages applied through one pad PD of the pad portion PDA to the P data lines DL (P being a positive integer of 2 or more), and as a result, the number of the plurality of pads PD may be reduced. The first distribution circuit 710 may be located on the third side of the display area DAA of the display panel 100. For example, the first distribution circuit 710 may be located on one side of the display area DAA in the second direction DR2. That is, the first distribution circuit 710 may be located on the lower side of the display area DAA.

The second distribution circuit 720 distributes signals applied through the pad portion PDA to the scan driver 610, the emission driver 620, and the data lines DL. The second distribution circuit 720 may be configured to inspect the operation of each of the pixels PX in the display area DAA. The second distribution circuit 720 may be located on the fourth side of the display area DAA of the display panel 100. For example, the second distribution circuit 720 may be located on the other side of the display area DAA in the second direction DR2. That is, the second distribution circuit 720 may be located on the upper side of the display area DAA. However, the second distribution circuit 720 may be omitted.

The power connection portion PCA refers to the area in which the second electrode of the light-emitting element LE (see FIG. 3) and the power connection electrode to which the first driving voltage VSS (see FIG. 2) is applied are connected, to apply the first driving voltage VSS to the second electrode of the light-emitting element LE (see FIG. 3).

The power connection portion PCA may be located to surround the display area DAA (as used herein, “surround” may mean “surround in plan view”). In addition, the power connection portion PCA may be located outside the scan driver 610, the emission driver 620, the first distribution circuit 710, and the second distribution circuit 720. For example, the power connection portion PCA may be located closer to the edge of the display panel 100 than the scan driver 610, the emission driver 620, the first distribution circuit 710, and the second distribution circuit 720. The power connection portion PCA may be located to surround the scan driver 610, the emission driver 620, the first distribution circuit 710, and the second distribution circuit 720. However, the present specification is not limited thereto, and the power connection portion PCA may overlap at least one of the scan driver 610, the emission driver 620, the first distribution circuit 710, or the second distribution circuit 720 in the third direction DR3.

The dam DAM may be a structure for reducing or preventing the likelihood of an organic encapsulation layer TFE2 of an encapsulation layer TFE (see FIG. 8), which is for encapsulating the light-emitting elements LE (see FIG. 3), overflowing to the pad portion PDA.

The dam DAM may be arranged to surround the display area DAA. In addition, the dam DAM may be located outside the scan driver 610, the emission driver 620, the first distribution circuit 710, and the second distribution circuit 720. For example, the dam DAM may be located closer to the edge of the display panel 100 than the scan driver 610, the emission driver 620, the first distribution circuit 710, and the second distribution circuit 720. The dam DAM may be located to surround the scan driver 610, the emission driver 620, the first distribution circuit 710, and the second distribution circuit 720. However, the present specification is not limited thereto, and the dam DAM may overlap at least one of the scan driver 610, the emission driver 620, the first distribution circuit 710, or the second distribution circuit 720 in the third direction DR3.

In addition, the dam DAM may be located outside the power connection portion PCA. For example, the dam DAM may be located closer to the edge of the display panel 100 than the power connection portion PCA. The dam DAM may be located to surround the power connection portion PCA.

According to one or more embodiments, the display device 10 may include the sealing dam DAR and the cover layer DCL that are located in the display panel 100. The sealing dam DAR may be located outside the dam DAM to surround the display area DAA and the dam DAM. The scan driver 610, the emission driver 620, the first distribution circuit 710, and the second distribution circuit 720 may be located in a region surrounded by the sealing dam DAR. In addition, the power connection portion PCA, and inspection pads, an electrostatic protection portion, a moisture permeation reduction portion, and a crack reduction portion that are not illustrated in the drawing may be further located within the region surrounded by the sealing dam DAR.

The cover layer DCL may be located in the region surrounded by the sealing dam DAR. The cover layer DCL may be located to cover at least the pixels PX of the display area DAA or a light-emitting element layer EML (see FIG. 8). For example, the sealing dam DAR may be located outside the dam DAM in the non-display area NDA, and the cover layer DCL may be located over some portions of the display area DAA and the non-display area NDA to overlap the plurality of pixels PX, the scan driver 610, the emission driver 620, the first distribution circuit 710, the second distribution circuit 720, the power connection portion PCA, and the dam DAM. The cover layer DCL is the uppermost layer of the display panel 100, and may protect the components located in the display panel 100.

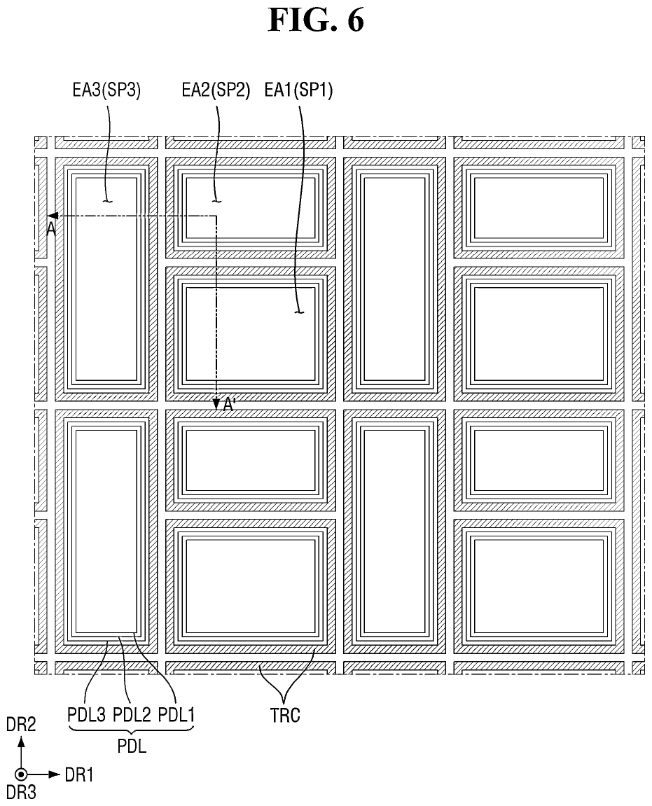

FIG. 6 is a plan view showing first electrodes and emission areas of a plurality of pixels located in a display area of FIG. 4, and a pixel-defining layer.

Referring to FIG. 6, each of the plurality of pixels PX (see FIG. 2) may include a first sub-pixel SP1, a second sub-pixel SP2, and a third sub-pixel SP3. The first to third sub-pixels SP1, SP2, and SP3 may include emission areas EA1, EA2, and EA3, respectively. For example, the first sub-pixel SP1 may include the first emission area EA1, the second sub-pixel SP2 may include the second emission area EA2, and the third sub-pixel SP3 may include the third emission area EA3.

Each of the first emission area EA1, the second emission area EA2, and the third emission area EA3 may be an area defined by a pixel-defining layer PDL. For example, each of the first emission area EA1, the second emission area EA2, and the third emission area EA3 may be an area defined by a first pixel-defining layer PDL1.

The length of the third emission area EA3 in the first direction DR1 may be less than the length of the first emission area EA1 in the first direction DR1, and may be less than the length of the second emission area EA2 in the first direction DR1. The length of the first emission area EA1 in the first direction DR1 and the length of the second emission area EA2 in the first direction DR1 may be substantially the same.

In each of the plurality of pixels PX, the first emission area EA1 and the second emission area EA2 may be adjacent to each other in the second direction DR2. Further, the first emission area EA1 and the third emission area EA3 may be adjacent to each other in the first direction DR1. Further, the second emission area EA2 and the third emission area EA3 may be adjacent to each other in the first direction DR1. The area of the first emission area EA1, the area of the second emission area EA2, and the area of the third emission area EA3 may be different.

The first emission area EA1 may emit light of a first color, the second emission area EA2 may emit light of a second color, and the third emission area EA3 may emit light of a third color. Here, the light of the first color may be light of a red wavelength band, the light of the second color may be light of a green wavelength band, and the light of the third color may be light of a blue wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

A first electrode AND (see FIG. 8) of the light-emitting element LE (see FIG. 3) may have a rectangular shape in plan view. The planar shape of the first electrode AND of the light-emitting element LE may be different in the first sub-pixel SP1, the second sub-pixel SP2, and the third sub-pixel SP3. For example, the first electrode AND of the first sub-pixel SP1 and the first electrode AND of the second sub-pixel SP2 may have a rectangular planar shape having a long side in the first direction DR1 and a short side in the second direction DR2. The first electrode AND of the third sub-pixel SP3 may have a rectangular shape, in plan view, having a short side in the first direction DR1 and a long side in the second direction DR2. The length of the first electrode AND of the third sub-pixel SP3 in the first direction DR1 may be shorter than the length of the first electrode AND of each of the first sub-pixel SP1 and the second sub-pixel SP2 in the first direction DR1. The length of the first electrode AND of the first sub-pixel SP1 in the second direction DR2 may be longer than the length of the first electrode AND of the second sub-pixel SP2 in the second direction DR2.

The first electrode AND of the light-emitting element LE may be connected to a reflective electrode layer RL (see FIG. 8) through a tenth via VA10 (see FIG. 8). The tenth via VA10 may overlap the first pixel-defining layer PDL1, a second pixel-defining layer PDL2, and a third pixel-defining layer PDL3 in the third direction DR3.

At least one trench TRC may be a structure for cutting off at least one charge generation layer of a light-emitting stack IL (see FIG. 8) between the neighboring emission areas EA1, EA2, and EA3. At least one trench TRC may be located between the first emission area EA1 and the second emission area EA2, between the first emission area EA1 and the third emission area EA3, and between the second emission area EA2 and the third emission area EA3. For example, at least one trench TRC may be located between the first electrode AND of the first sub-pixel SP1 and the first electrode AND of the second sub-pixel SP2, between the first electrode AND of the first sub-pixel SP1 and the first electrode AND of the third sub-pixel SP3, and between the first electrode AND of the second sub-pixel SP2 and the first electrode AND of the third sub-pixel SP3.

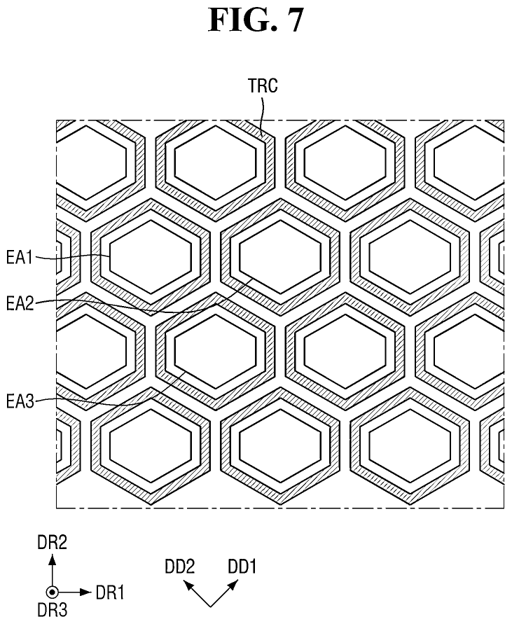

FIG. 7 is a plan view showing first electrodes and emission areas of a plurality of sub-pixels, and a pixel-defining layer according to one or more other embodiments.

Because the one or more embodiments corresponding to FIG. 7 is substantially the same as the one or more embodiments corresponding to FIG. 6 except that the planar shapes of the first emission area EA1, the second emission area EA2, and the third emission area EA3 are different from those of the one or more embodiments corresponding to FIG. 6, description overlapping with the one or more embodiments corresponding to FIG. 6 will be omitted.

Referring to FIG. 7, the first emission area EA1, the second emission area EA2, and the third emission area EA3 may be located in a hexagonal structure having a hexagonal shape in plan view. In this case, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 may be a direction between the first direction DR1 and the second direction DR2, and may refer to a direction inclined by 45 degrees with respect to the first direction DR1 and with respect to the second direction DR2. The second diagonal direction DD2 may be a direction perpendicular to the first diagonal direction DD1.

Although it is illustrated in FIGS. 6 and 7 that each of the plurality of pixels PX includes the three emission areas EA1, EA2, and EA3, the present disclosure is not limited thereto. That is, each of the plurality of pixels PX may include four emission areas.

In addition, the disposition of the emission areas EA1, EA2, and EA3 of the plurality of pixels PX is not limited to that illustrated in FIGS. 6 and 7. For example, the emission areas of the plurality of pixels PX may be located in a stripe structure in which the emission areas are arranged in the first direction DR1, a PenTile® structure in which the emission areas are arranged in a diamond shape, or the like (PenTile® and PENTILE™ being registered trademarks of Samsung Display Co., Ltd., Republic of Korea).

FIG. 8 is a schematic cross-sectional view taken along the line A-A′ of FIG. 6.

Referring to FIG. 8, the display panel 100 may include a semiconductor backplane SBP, a light-emitting element backplane EBP, the light-emitting element layer EML, the encapsulation layer TFE, an adhesive layer ADL, a color filter layer CFL, a lens array layer LNS, and the cover layer DCL. In one or more embodiments, the display panel 100 may further include a polarizing plate located on the cover layer DCL.

The semiconductor backplane SBP includes the semiconductor substrate SSUB including a plurality of pixel transistors PTR, a plurality of semiconductor insulating layers covering the plurality of pixel transistors PTR, and a plurality of contact terminals CTE electrically connected to the plurality of pixel transistors PTR, respectively. The plurality of pixel transistors PTR may be the first to sixth transistors T1, T2, T3, T4, T5, and T6 described with reference to FIG. 3.

The semiconductor substrate SSUB may be a silicon substrate, a germanium substrate, or a silicon-germanium substrate. The semiconductor substrate SSUB may be a substrate doped with a first type impurity. A plurality of well regions WA may be located on the top surface of the semiconductor substrate SSUB. The plurality of well regions WA may be regions doped with a second type impurity. The second type impurity may be different from the aforementioned first type impurity. For example, when the first type impurity is a p-type impurity, the second type impurity may be an n-type impurity. Alternatively, when the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode thereof, and a channel region CH located between the source region SA and the drain region DA.

A lower insulating layer BINS may be located between a gate electrode GE and the well region WA. A side insulating layer SINS may be located on the side surface of the gate electrode GE. The side insulating layer SINS may be located on the lower insulating layer BINS.

Each of the source region SA and the drain region DA may be a region doped with the first type impurity. A gate electrode GE of the pixel transistor PTR may overlap the well region WA in the third direction DR3. The channel region CH may overlap the gate electrode GE in the third direction DR3. The source region SA may be located on one side of the gate electrode GE, and the drain region DA may be located on the other side of the gate electrode GE.

Each of the plurality of well regions WA further includes a first low-concentration impurity region LDD1 located between the channel region CH and the source region SA, and a second low-concentration impurity region LDD2 located between the channel region CH and the drain region DA. The first low-concentration impurity region LDD1 may be a region having a lower impurity concentration than the source region SA due to the lower insulating layer BINS. The second low-concentration impurity region LDD2 may be a region having a lower impurity concentration than the drain region DA due to the lower insulating layer BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that punch-through and hot carrier phenomena that might be caused by a short channel may be reduced or prevented.

A first semiconductor insulating layer SINS1 may be located on the semiconductor substrate SSUB. The first semiconductor insulating layer SINS1 may be formed of silicon carbonitride (SiCN) or a silicon oxide (SiOₓ)-based inorganic layer, but is not limited thereto.

A second semiconductor insulating layer SINS2 may be located on the first semiconductor insulating layer SINS1. The second semiconductor insulating layer SINS2 may be formed of a silicon oxide (SiOₓ)-based inorganic layer, but is not limited thereto.

The plurality of contact terminals CTE may be located on the second semiconductor insulating layer SINS2. Each of the plurality of contact terminals CTE may be connected to any one of the gate electrode GE, the source region SA, or the drain region DA of each of the pixel transistors PTR through holes penetrating the first semiconductor insulating layer SINS1 and the second semiconductor insulating layer SINS2. The plurality of contact terminals CTE may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. The third semiconductor insulating layer SINS3 may be located on the second semiconductor insulating layer SINS2. The third semiconductor insulating layer SINS3 may also be located on a side surface of each of the portions of the plurality of contact terminals CTE located on the second semiconductor insulating layer SINS2. The top surface of each of the plurality of contact terminals CTE may be exposed without being covered by the third semiconductor insulating layer SINS3. The third semiconductor insulating layer SINS3 may be formed of a silicon oxide (SiOₓ)-based inorganic layer, but is not limited thereto.

The semiconductor substrate SSUB may be replaced with a glass substrate or a polymer resin substrate, such as polyimide. In this case, thin film transistors may be located on the glass substrate or the polymer resin substrate. The glass substrate may be a rigid substrate that does not bend, and the polymer resin substrate may be a flexible substrate that can be bent or curved.

The light-emitting element backplane EBP includes first to eighth metal layers ML1, ML2, ML3, ML4, ML5, ML6, ML7, and ML8, the reflective electrode layer RL, and a plurality of vias VA1, VA2, VA3, VA4, VA5, VA6, VA7, VA8, VA9, and VA10. In addition, the light-emitting element backplane EBP includes a plurality of interlayer insulating layers INS1, INS2, INS3, INS4, INS5, INS6, INS7, INS8, INS9, INS10 and INS11 located between the semiconductor backplane SBP, the first to eighth metal layers ML1, ML2, ML3, ML4, ML5, ML6, ML7, and ML8, the reflective electrode layer RL, and the light-emitting element layer EML.

The first to eighth metal layers ML1, ML2, ML3, ML4, ML5, ML6, ML7, and ML8 may connect the plurality of contact terminals CTE exposed from the semiconductor backplane SBP to form a circuit of the sub-pixel SP shown in FIG. 3. The first to sixth transistors T1, T2, T3, T4, T5, and T6 (see FIG. 3) may be formed on the semiconductor backplane SBP, and the connection of the first to sixth transistors T1, T2, T3, T4, T5, and T6 and the first and second capacitors C1 and C2 (see FIG. 3) may be accomplished through the first to eighth metal layers ML1, ML2, ML3, ML4, ML5, ML6, ML7, and ML8. In addition, the connection between the drain region corresponding to the drain electrode of the fourth transistor T4, the source region corresponding to the source electrode of the fifth transistor T5, and the first electrode of the light-emitting element LE may also be accomplished through the first to eighth metal layers ML1, ML2, ML3, ML4, ML5, ML6, ML7, and ML8.

The first interlayer insulating layer INS1 may be located on the semiconductor backplane SBP. Each of the first vias VA1 may penetrate the first interlayer insulating layer INS1 to be connected to the contact terminal CTE exposed from the semiconductor backplane SBP. Each of the first metal layers ML1 may be located on the first interlayer insulating layer INS1 and may be connected to the first via VA1.

The second interlayer insulating layer INS2 may be located on the first interlayer insulating layer INS1 and the first metal layers ML1. Each of the second vias VA2 may penetrate the second interlayer insulating layer INS2, and may be connected to the exposed first metal layer ML1. Each of the second metal layers ML2 may be located on the second interlayer insulating layer INS2 and may be connected to the second via VA2.

The third interlayer insulating layer INS3 may be located on the second interlayer insulating layer INS2 and the second metal layers ML2. Each of the third vias VA3 may penetrate the third interlayer insulating layer INS3, and may be connected to the exposed second metal layer ML2. Each of the third metal layers ML3 may be located on the third interlayer insulating layer INS3 and may be connected to the third via VA3.

The fourth interlayer insulating layer INS4 may be located on the third interlayer insulating layer INS3 and the third metal layers ML3. Each of the fourth vias VA4 may penetrate the fourth interlayer insulating layer INS4, and may be connected to the exposed third metal layer ML3. Each of the fourth metal layers ML4 may be located on the fourth interlayer insulating layer INS4 and may be connected to the fourth via VA4.

The fifth interlayer insulating layer INS5 may be located on the fourth interlayer insulating layer INS4 and the fourth metal layers ML4. Each of the fifth vias VA5 may penetrate the fifth interlayer insulating layer INS5, and may be connected to the exposed fourth metal layer ML4. Each of the fifth metal layers ML5 may be located on the fifth interlayer insulating layer INS5 and may be connected to the fifth via VA5.

The sixth interlayer insulating layer INS6 may be located on the fifth interlayer insulating layer INS5 and the fifth metal layers ML5. Each of the sixth vias VA6 may penetrate the sixth interlayer insulating layer INS6, and may be connected to the exposed fifth metal layer ML5. Each of the sixth metal layers ML6 may be located on the sixth interlayer insulating layer INS6 and may be connected to the sixth via VA6.

The seventh interlayer insulating layer INS7 may be located on the sixth interlayer insulating layer INS6 and the sixth metal layers ML6. Each of the seventh vias VA7 may penetrate the seventh interlayer insulating layer INS7, and may be connected to the exposed sixth metal layer ML6. Each of the seventh metal layers ML7 may be located on the seventh interlayer insulating layer INS7 and may be connected to the seventh via VA7.

The eighth interlayer insulating layer INS8 may be located on the seventh interlayer insulating layer INS7 and the seventh metal layers ML7. Each of the eighth vias VA8 may penetrate the eighth interlayer insulating layer INS8, and may be connected to the exposed seventh metal layer ML7. Each of the eighth metal layers ML8 may be located on the eighth interlayer insulating layer INS8 and may be connected to the eighth via VA8.

The first to eighth metal layers ML1, ML2, ML3, ML4, ML5, ML6, ML7, and ML8 and the first to eighth vias VA1, VA2, VA3, VA4, VA5, VA6, VA7, and VA8 may be formed of substantially the same material. The first to eighth metal layers ML1, ML2, ML3, ML4, ML5, ML6, ML7, and ML8 and the first to eighth vias VA1, VA2, VA3, VA4, VA5, VA6, VA7, and VA8 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. The first to eighth vias VA1, VA2, VA3, VA4, VA5, VA6, VA7, and VA8 may be made of substantially the same material. First to eighth interlayer insulating layers INS1, INS2, INS3, INS4, INS5, INS6, INS7, and INS8 may be formed of a silicon oxide (SiOₓ)-based inorganic layer, but are not limited thereto.

The thicknesses of the first metal layer ML1, the second metal layer ML2, the third metal layer ML3, the fourth metal layer ML4, the fifth metal layer ML5, and the sixth metal layer ML6 may be greater than the thicknesses of the first via VA1, the second via VA2, the third via VA3, the fourth via VA4, the fifth via VA5, and the sixth via VA6, respectively. The thickness of each of the second metal layer ML2, the third metal layer ML3, the fourth metal layer ML4, the fifth metal layer ML5, and the sixth metal layer ML6 may be greater than the thickness of the first metal layer ML1. The thickness of the second metal layer ML2, the thickness of the third metal layer ML3, the thickness of the fourth metal layer ML4, the thickness of the fifth metal layer ML5, and the thickness of the sixth metal layer ML6 may be substantially the same. For example, the thickness of the first metal layer ML1 may be approximately 1360 Å, the thickness of each of the second metal layer ML2, the third metal layer ML3, the fourth metal layer ML4, the fifth metal layer ML5, and the sixth metal layer ML6 may be approximately 1440 Å, and the thickness of each of the first via VA1, the second via VA2, the third via VA3, the fourth via VA4, the fifth via VA5, and the sixth via VA6 may be approximately 1150 Å.

The thickness of each of the seventh metal layer ML7 and the eighth metal layer ML8 may be greater than the thickness of the first metal layer ML1, the thickness of the second metal layer ML2, the thickness of the third metal layer ML3, the thickness of the fourth metal layer ML4, the thickness of the fifth metal layer ML5, and the thickness of the sixth metal layer ML6. The thickness of each of the seventh metal layer ML7 and the eighth metal layer ML8 may be greater than the thickness of the seventh via VA7 and the thickness of the eighth via VA8. The thickness of each of the seventh via VA7 and the eighth via VA8 may be greater than the thickness of the first via VA1, the thickness of the second via VA2, the thickness of the third via VA3, the thickness of the fourth via VA4, the thickness of the fifth via VA5, and the thickness of the sixth via VA6. The thickness of the seventh metal layer ML7 and the thickness of the eighth metal layer ML8 may be substantially the same. For example, the thickness of each of the seventh metal layer ML7 and the eighth metal layer ML8 may be approximately 9000 Å. The thickness of each of the seventh via VA7 and the eighth via VA8 may be approximately 6000 Å.

The ninth interlayer insulating layer INS9 may be located on the eighth interlayer insulating layer INS8 and the eighth metal layers ML8. The ninth interlayer insulating layer INS9 may be formed of a silicon oxide (SiOₓ)-based inorganic layer, but is not limited thereto.

Each of the ninth vias VA9 may penetrate the ninth interlayer insulating layer INS9, and may be connected to the exposed eighth metal layer ML8. The ninth vias VA9 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. The thickness of the ninth via VA9 may be approximately 16500 Å.

The reflective electrode layer RL may be located on the ninth interlayer insulating layer INS9. The reflective electrode layer RL may include at least one reflective electrode RL1, RL2, RL3, or RL4. For example, the reflective electrode layer RL may include the first to fourth reflective electrodes RL1, RL2, RL3, and RL4 as shown in FIG. 8.

Each of the first reflective electrodes RL1 may be located on the ninth interlayer insulating layer INS9, and may be connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the first reflective electrodes RL1 may include titanium nitride (TiN).

Each of the second reflective electrodes RL2 may be located on the first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the second reflective electrodes RL2 may include aluminum (Al).

Each of the third reflective electrodes RL3 may be located on the second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the third reflective electrodes RL3 may include titanium nitride (TiN).

The fourth reflective electrodes RL4 may be respectively located on the third reflective electrodes RL3. The fourth reflective electrodes RL4 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the fourth reflective electrodes RL4 may include titanium (Ti).

Because the second reflective electrode RL2 is an electrode that substantially reflects light from the light-emitting elements LE (see FIG. 3), the thickness of the second reflective electrode RL2 may be greater than the thickness of each of the first reflective electrode RL1, the third reflective electrode RL3, and the fourth reflective electrode RL4. For example, the thickness of each of the first reflective electrode RL1, the third reflective electrode RL3, and the fourth reflective electrode RL4 may be approximately 100 Å, and the thickness of the second reflective electrode RL2 may be 850 Å.

The tenth interlayer insulating layer INS10 may be located on the ninth interlayer insulating layer INS9. The tenth interlayer insulating layer INS10 may be located between the reflective electrode layers RL adjacent to each other. The tenth interlayer insulating layer INS10 may be located on the reflective electrode layer RL in the third sub-pixel SP3. The tenth interlayer insulating layer INS10 may be formed of a silicon oxide (SiOₓ)-based inorganic layer, but is not limited thereto.

The eleventh interlayer insulating layer INS11 may be located on the tenth interlayer insulating layer INS10 and the reflective electrode layer RL. The eleventh interlayer insulating layer INS11 may be formed of a silicon oxide (SiOₓ)-based inorganic layer, but is not limited thereto.

In at least one of the first sub-pixel SP1, the second sub-pixel SP2, or the third sub-pixel SP3, the tenth interlayer insulating layer INS10 and the eleventh interlayer insulating layer INS11 may be omitted under the first electrode AND in consideration of the resonance distance of the light emitted from the light-emitting elements LE.

For example, the first electrode AND of the first sub-pixel SP1 may be directly located on the fourth reflective electrode RL4, and the first electrode AND of the first sub-pixel SP1 may not overlap the tenth interlayer insulating layer INS10 and the eleventh interlayer insulating layer INS11. The first electrode AND of the second sub-pixel SP2 may be located on the eleventh interlayer insulating layer INS11, and the eleventh interlayer insulating layer INS11 may be directly located on the fourth reflective electrode RL4. That is, the first electrode AND of the second sub-pixel SP2 may not overlap the tenth interlayer insulating layer INS10. The first electrode AND of the third sub-pixel SP3 may be located on the eleventh interlayer insulating layer INS11, and may overlap the tenth interlayer insulating layer INS10.

In one or more embodiments, the distance between the first electrode AND and the reflective electrode layer RL may be different in the first sub-pixel SP1, the second sub-pixel SP2, and the third sub-pixel SP3. To adjust the distance from the reflective electrode layer RL to a second electrode CAT according to the main wavelength of the light emitted from each of the first sub-pixel SP1, the second sub-pixel SP2, and the third sub-pixel SP3, the presence or absence of the tenth interlayer insulating layer INS10 and the eleventh interlayer insulating layer INS11 may be determined in each of the first sub-pixel SP1, the second sub-pixel SP2, and the third sub-pixel SP3. For example, in FIG. 8, the distance between the first electrode AND and the reflective electrode layer RL in the third sub-pixel SP3 may be greater than the distance between the first electrode AND and the reflective electrode layer RL in the second sub-pixel SP2, and may be greater than the distance between the first electrode AND and the reflective electrode layer RL in the first sub-pixel SP1. The distance between the first electrode AND and the reflective electrode layer RL in the second sub-pixel SP2 may be greater than the distance between the first electrode AND and the reflective electrode layer RL in the first sub-pixel SP1. However, the present disclosure is not limited thereto. The distance between the first electrode AND and the reflective electrode layer RL in each of the sub-pixels SP1, SP2, and SP3 may be variously modified and designed.

In addition, although the tenth interlayer insulating layer INS10 and the eleventh interlayer insulating layer INS11 are illustrated in the drawing, a twelfth interlayer insulating layer may be further arranged under the first electrode AND of the sub-pixel SP (see FIG. 3). In this case, the eleventh interlayer insulating layer INS11 and the twelfth interlayer insulating layer INS12 may be located under the first electrode AND of the second sub-pixel SP2, and the tenth interlayer insulating layer INS10, the eleventh interlayer insulating layer INS11, and the twelfth interlayer insulating layer INS12 may be located under the first electrode AND of the third sub-pixel SP3.

Each of the tenth vias VA10 may penetrate the tenth interlayer insulating layer INS10 and/or an eleventh interlayer insulating layer INS11 in the second sub-pixel SP2 and the third sub-pixel SP3, and may be connected to the exposed fourth reflective electrode RL4. The tenth vias VA10 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. The thickness of the tenth via VA10 in the second sub-pixel SP2 may be less than the thickness of the tenth via VA10 in the third sub-pixel SP3.

The light-emitting element layer EML may be located on the light-emitting element backplane EBP. The light-emitting element layer EML may include the light-emitting elements LE each having the first electrode AND, the light-emitting stack IL, and the second electrode CAT, the pixel-defining layer PDL, and the plurality of trenches TRC.

The first electrode AND of each of the light-emitting elements LE may be located on the tenth interlayer insulating layer INS10 or the eleventh interlayer insulating layer INS11, and may be connected to the tenth via VA10, or may be located on the fourth reflective electrode RL4. In the second sub-pixel SP2 and the third sub-pixel SP3. The first electrode AND of each of the light-emitting elements LE may be connected to the drain region DA or source region SA of the pixel transistor PTR through the tenth via VA10, the first to fourth reflective electrodes RL1, RL2, RL3, and RL4, the first to ninth vias VA1, VA2, VA3, VA4, VA5, VA6, VA7, VA8, and VA9, the first to eighth metal layers ML1, ML2, ML3, ML4, ML5, ML6, ML7, and ML8, and the contact terminal CTE. In the first sub-pixel SP1, the first electrode AND of each of the light-emitting elements LE may be connected to the drain region DA or source region SA of the pixel transistor PTR through the first to fourth reflective electrodes RL1, RL2, RL3, and RL4, the first to ninth vias VA1, VA2, VA3, VA4, VA5, VA6, VA7, VA8, and VA9, the first to eighth metal layers ML1, ML2, ML3, ML4, ML5, ML6, ML7, and ML8, and the contact terminal CTE. The first electrode AND of each of the light-emitting elements LE may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the first electrode AND of each of the light-emitting elements LE may be titanium nitride (TiN).

The pixel-defining layer PDL may be located on a part of the first electrode AND of each of the light-emitting elements LE. The pixel-defining layer PDL may cover the edge of the first electrode AND of each of the light-emitting elements LE. The pixel-defining layer PDL may serve to partition the first emission areas EA1, the second emission areas EA2, and the third emission areas EA3.

The first emission area EA1 may be defined as an area in which the first electrode AND, the light-emitting stack IL, and the second electrode CAT are sequentially stacked in the first sub-pixel SP1 to emit light. The second emission area EA2 may be defined as an area in which the first electrode AND, the light-emitting stack IL, and the second electrode CAT are sequentially stacked in the second sub-pixel SP2 to emit light. The third emission area EA3 may be defined as an area in which the first electrode AND, the light-emitting stack IL, and the second electrode CAT are sequentially stacked in the third sub-pixel SP3 to emit light.

The pixel-defining layer PDL may include first to third pixel-defining layers PDL1, PDL2, and PDL3. The first pixel-defining layer PDL1 may be located on the edge of the first electrode AND of each of the light-emitting elements LE. The second pixel-defining layer PDL2 may be located on the first pixel-defining layer PDL1. The third pixel-defining layer PDL3 may be located on the second pixel-defining layer PDL2. The first pixel-defining layer PDL1, the second pixel-defining layer PDL2, and the third pixel-defining layer PDL3 may be formed of a silicon oxide (SiOₓ)-based inorganic layer, but are not limited thereto. The first pixel-defining layer PDL1, the second pixel-defining layer PDL2, and the third pixel-defining layer PDL3 may each have a thickness of about 500 Å.

When the first pixel-defining layer PDL1, the second pixel-defining layer PDL2, and the third pixel-defining layer PDL3 are formed as one pixel-defining layer, the height of the one pixel-defining layer increases, so that a first inorganic encapsulation layer TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

To reduce or prevent the likelihood of the first inorganic encapsulation layer TFE1 being cut off due to the step coverage, the first pixel-defining layer PDL1, the second pixel-defining layer PDL2, and the third pixel-defining layer PDL3 may have a cross-sectional structure having a stepped portion. For example, the width of the first pixel-defining layer PDL1 may be greater than the width of the second pixel-defining layer PDL2 and the width of the third pixel-defining layer PDL3. The width of the second pixel-defining layer PDL2 may be greater than the width of the third pixel-defining layer PDL3. The width of the first pixel-defining layer PDL1 may refer to the horizontal length of the first pixel-defining layer PDL1 defined in the first direction DR1 and the second direction DR2 (see FIG. 6).

Each of the plurality of trenches TRC may penetrate the first pixel-defining layer PDL1, the second pixel-defining layer PDL2, and the third pixel-defining layer PDL3. In each of the plurality of trenches TRC, a portion of the tenth interlayer insulating layer INS10 may be dug/removed, and the eleventh interlayer insulating layer INS11 may have a shape through which the eleventh interlayer insulating layer INS11 is penetrated.

At least one trench TRC may be located between adjacent sub-pixels SP1, SP2, and SP3. FIG. 7 illustrates that two trenches TRC are located between the adjacent sub-pixels SP1, SP2, and SP3, but the present disclosure is not limited thereto.

The light-emitting stack IL may include a plurality of intermediate layers. FIG. 8 illustrates that the light-emitting stack IL has a three-tandem structure including a first intermediate layer IL1, a second intermediate layer IL2, and a third intermediate layer IL3, but the present disclosure is not limited thereto. For example, the light-emitting stack IL may have a two-tandem structure including two intermediate layers.

In the three-tandem structure, the light-emitting stack IL may have a tandem structure including a plurality of intermediate layers IL1, IL2, and IL3 that emit different lights. For example, the light-emitting stack IL may include the first intermediate layer IL1 that emits light of the first color, the second intermediate layer IL2 that emits light of the third color, and the third intermediate layer IL3 that emits light of the second color. The first intermediate layer IL1, the second intermediate layer IL2, and the third intermediate layer IL3 may be sequentially stacked.

The first intermediate layer IL1 may have a structure in which a first hole transport layer, a first organic light-emitting layer that emits light of the first color, and a first electron transport layer are sequentially stacked. The second intermediate layer IL2 may have a structure in which a second hole transport layer, a second organic light-emitting layer that emits light of the third color, and a second electron transport layer are sequentially stacked. The third intermediate layer IL3 may have a structure in which a third hole transport layer, a third organic light-emitting layer that emits light of the second color, and a third electron transport layer are sequentially stacked.

A first charge generation layer for supplying charges to the second intermediate layer IL2 and for supplying electrons to the first intermediate layer IL1 may be located between the first intermediate layer IL1 and the second intermediate layer IL2. The first charge generation layer may include an N-type charge generation layer that supplies electrons to the first intermediate layer IL1 and a P-type charge generation layer that supplies holes to the second intermediate layer IL2. The N-type charge generation layer may include a dopant of a metal material.

A second charge generation layer for supplying charges to the third intermediate layer IL3 and for supplying electrons to the second intermediate layer IL2 may be located between the second intermediate layer IL2 and the third intermediate layer IL3. The second charge generation layer may include an N-type charge generation layer that supplies electrons to the second intermediate layer IL2 and a P-type charge generation layer that supplies holes to the third intermediate layer IL3.

The first intermediate layer IL1 may be located on the first electrodes AND and the pixel-defining layer PDL, and may be located on the bottom surface of each trench TRC. Due to the trench TRC, the first intermediate layer IL1 may be cut off between adjacent sub-pixels SP1, SP2, and SP3. The second intermediate layer IL2 may be located on the first intermediate layer IL1. Due to the trench TRC, the second intermediate layer IL2 may be cut off between adjacent sub-pixels SP1, SP2, and SP3. A void or an empty space ESS may be located between the first intermediate layer IL1 and the second intermediate layer IL2. The third intermediate layer IL3 may be located on the second intermediate layer IL2. The third intermediate layer IL3 may be located to cover the second intermediate layer IL2 in each of the trenches TRC without being cut off by the trench TRC. That is, in the three-tandem structure, each of the trenches TRC may be a structure for cutting off the first charge generation layer, the second charge generation layer, and/or the first and second intermediate layers IL1 and/or IL2 of the light-emitting element layer EML between the adjacent sub-pixels SP1, SP2, and SP3. Additionally, in the two-tandem structure, each of the trenches TRC may be a structure for cutting off the charge generation layer located between a lower intermediate layer and an upper intermediate layer, and the lower intermediate layer.

To stably cut off the first and/or second intermediate layers IL1 and/or IL2 of the light-emitting element layer EML between the adjacent sub-pixels SP1, SP2, and SP3, the height of each trench TRC may be greater than the height of the pixel-defining layer PDL. The height/depth of each of the plurality of trenches TRC refers to the length of each of the plurality of trenches TRC in the third direction DR3. The height of the pixel-defining layer PDL refers to the length of the pixel-defining layer PDL in the third direction DR3. To cut off the first to third intermediate layers IL1, IL2, and IL3 of the light-emitting element layer EML between the neighboring sub-pixels SP1, SP2, and SP3, another structure may exist instead of the trench TRC. For example, instead of the trench TRC, a reverse tapered partition wall may be located on the pixel-defining layer PDL.

The number of the intermediate layers IL1, IL2, and IL3 that emit different lights is not limited to that shown in FIG. 8. For example, the light-emitting stack IL may include two intermediate layers. In this case, one of the two intermediate layers may be substantially the same as the first intermediate layer IL1, and the other may include a second hole transport layer, a second organic light-emitting layer, a third organic light-emitting layer, and a second electron transport layer. In this case, a charge generation layer for supplying electrons to one intermediate layer and for supplying charges to the other intermediate layer may be located between the two intermediate layers.

In addition, FIG. 8 illustrates that the first to third intermediate layers IL1, IL2, and IL3 are all located in the first emission area EA1, the second emission area EA2, and the third emission area EA3, but the present disclosure is not limited thereto. For example, the first intermediate layer IL1 may be located in the first emission area EA1 and may be omitted in the second emission area EA2 and the third emission area EA3. Furthermore, the second intermediate layer IL2 may be located in the second emission area EA2 and may be omitted in the first emission area EA1 and the third emission area EA3. Further, the third intermediate layer IL3 may be located in the third emission area EA3 and may be omitted in the first emission area EA1 and the second emission area EA2. In this case, first to third color filters CF1, CF2, and CF3 of the optical layer OPL may be omitted.

The second electrode CAT may be located on the third intermediate layer IL3. The second electrode CAT may be located on the third intermediate layer IL3 in each of the plurality of trenches TRC. The second electrode CAT may be formed of a transparent conductive material (TCO), such as ITO or IZO that can transmit light or a semi-transmissive conductive material, such as magnesium (Mg), silver (Ag), or an alloy of Mg and Ag. When the second electrode CAT is formed of a semi-transmissive conductive material, the light emission efficiency may be improved in each of the first to third sub-pixels SP1, SP2, and SP3 due to a micro-cavity effect.

The encapsulation layer TFE may be located on the light-emitting element layer EML. The encapsulation layer TFE may include at least one inorganic layer TFE1 and/or TFE3 to reduce or prevent permeation of oxygen or moisture into the light-emitting element layer EML. In addition, the encapsulation layer TFE may include at least one organic layer to protect the light-emitting element layer EML from foreign substances, such as dust. For example, the encapsulation layer TFE may include the first inorganic encapsulation layer TFE1, an organic encapsulation layer TFE2, and a second inorganic encapsulation layer TFE3.

The first inorganic encapsulation layer TFE1 may be located on the second electrode CAT, the organic encapsulation layer TFE2 may be located on the first inorganic encapsulation layer TFE1, and the second inorganic encapsulation layer TFE3 may be located on the organic encapsulation layer TFE2. The first inorganic encapsulation layer TFE1 and the second inorganic encapsulation layer TFE3 may be formed of multiple layers in which one or more inorganic layers of silicon nitride (SiNₓ), silicon oxynitride (SiOₓN_{y}), silicon oxide (SiOₓ), titanium oxide (TiOₓ), or aluminum oxide (AlOₓ) layers are alternately stacked. The organic encapsulation layer TFE2 may be a monomer. Alternatively, the organic encapsulation layer TFE2 may be an organic layer, such as acryl resin, epoxy resin, phenolic resin, polyamide resin, polyimide resin or the like.

The adhesive layer ADL may be located on the encapsulation layer TFE. The adhesive layer ADL may be a layer for bonding the encapsulation layer TFE to a layer located thereon. The adhesive layer ADL may be a double-sided adhesive member. In addition, the adhesive layer ADL may be a transparent adhesive member, such as a transparent adhesive or a transparent adhesive resin.

The color filter layer CFL, the lens array layer LNS, and the cover layer DCL may be located on the adhesive layer ADL. The color filter layer CFL, the lens array layer LNS, and the cover layer DCL may constitute an optical layer of the display panel 100.

The color filter layer CFL may include the plurality of color filters CF1, CF2, and CF3 and may be located on the adhesive layer ADL. The first color filter CF1 may overlap the first emission area EA1 of the first sub-pixel SP1. The first color filter CF1 may transmit light of the first color (e.g., light of a red wavelength band). The first color filter CF1 may transmit light of the first color among light emitted from the first emission area EA1.

The second color filter CF2 may overlap the second emission area EA2 of the second sub-pixel SP2. The second color filter CF2 may transmit light of the second color (e.g., light of a green wavelength band). Thus, the second color filter CF2 may transmit light of the second color among light emitted from the second emission area EA2.

The third color filter CF3 may overlap the third emission area EA3 of the third sub-pixel SP3. The third color filter CF3 may transmit light of the third color (e.g., light of a blue wavelength band). Thus, the third color filter CF3 may transmit light of the third color among light emitted from the third emission area EA3.

The lens array layer LNS may be located on the color filter layer CFL in the display area DAA (see FIG. 3). The lens array layer LNS may include a plurality of lenses located in the display area DAA. The plurality of lenses may be located on the first color filter CF1, the second color filter CF2, and the third color filter CF3, respectively. Each of the plurality of lenses may be a structure for increasing a ratio of light directed to the front of the display device 10. Each of the plurality of lenses may have a cross-sectional shape that is convex in an upward direction.

The cover layer DCL may be located on the lens array layer LNS. The cover layer DCL may be directly located on the plurality of lenses of the lens array layer LNS. The cover layer DCL may have a refractive index (e.g., predetermined refractive index) so that light travels in the third direction DR3 at an interface between the plurality of lenses and the cover layer DCL. Additionally, the cover layer DCL may be a planarization layer. The cover layer DCL may be an organic layer, such as acryl resin, epoxy resin, phenolic resin, polyamide resin, polyimide resin or the like.

In one or more embodiments, a polarizing plate may be located on the cover layer DCL. The polarizing plate may be a structure for reducing or preventing visibility degradation caused by reflection of external light. The polarizing plate may include a linear polarizing plate and a phase retardation film. For example, the phase retardation film may be a λ/4 plate (quarter-wave plate), but is not limited thereto. However, when visibility degradation caused by reflection of external light is sufficiently overcome by the first to third color filters CF1, CF2, and CF3, the polarizing plate may be omitted.

As illustrated in FIG. 8, by forming the light-emitting element backplane EBP and the light-emitting element layer EML on the semiconductor substrate SSUB in which a plurality of transistors are formed, the size of the plurality of pixels PX may be greatly reduced, so that the display device 10 that displays high-resolution images may be provided.

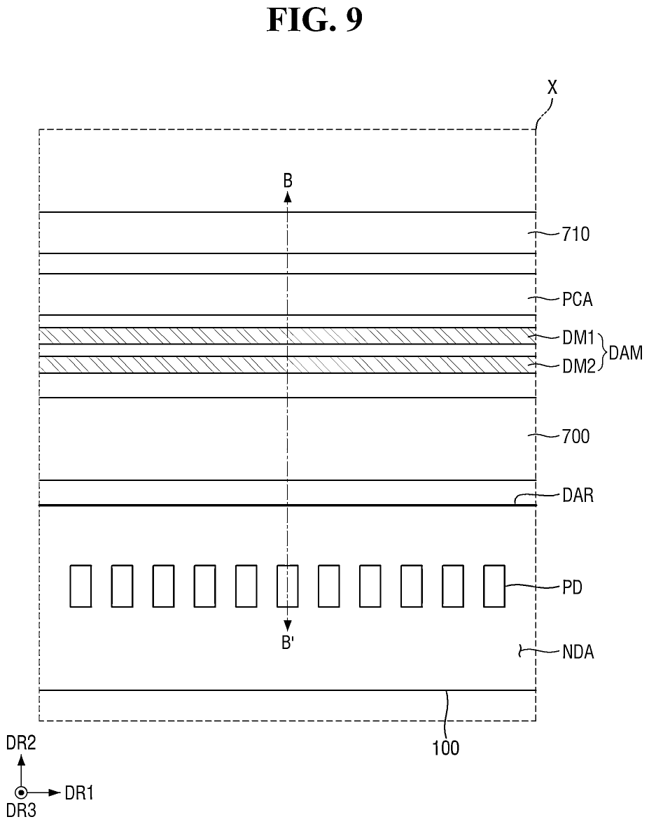

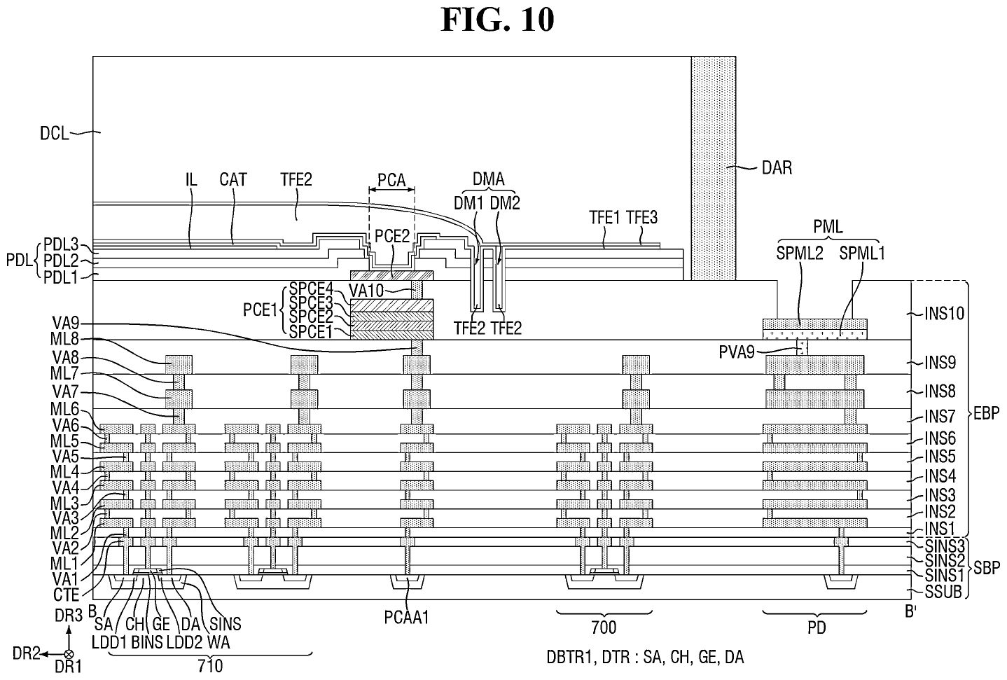

FIG. 9 is an enlarged view showing area X of FIG. 4. FIG. 10 is a schematic cross-sectional view taken along the line B-B′ of FIG. 9.

The area X of FIG. 4 may be an area located on the lower side, which is one side of the display area DAA in the second direction DR2. FIGS. 9 and 10 show the first distribution circuit 710, the power connection portion PCA, the dam DAM, the data driver 700, the pad PD, and the sealing dam DAR located on the lower side of the display area DAA.

Referring to FIGS. 9 and 10, the first distribution circuit 710, the power connection portion PCA, the dam DAM, the data driver 700, the sealing dam DAR, and the pad PD may be sequentially located in the second direction DR2 on the lower side of the display area DAA. However, the present disclosure is not limited thereto. In some embodiments, the power connection portion PCA may overlap the first distribution circuit 710 or the data driver 700 in the thickness direction, and the dam DAM may overlap the first distribution circuit 710 or the data driver 700 in the thickness direction.

The first distribution circuit 710 may include a plurality of first distribution transistors DBTR1. Because each of the plurality of first distribution transistors DBTR1 may be formed substantially the same as the pixel transistors PTR described in conjunction with FIG. 8, a detailed description of the plurality of first distribution transistors DBTR1 will be omitted. In addition, because the contact terminals CTE, the first to eighth metal layers ML1, ML2, ML3, ML4, ML5, ML6, ML7, and ML8 and the first to eighth vias VA1, VA2, VA3, VA4, VA5, VA6, VA7, and VA8 electrically connected to the plurality of first distribution transistors DBTR1 are also substantially the same as those described in conjunction with FIG. 8, a description thereof will be omitted.

The power connection portion PCA includes a first power connection area PCAA1 of the semiconductor substrate SSUB, a first power connection electrode PCE1, and a second power connection electrode PCE2.

The first driving voltage VSS (see FIG. 2) may be applied to the first power connection area PCAA1 of the semiconductor substrate SSUB.

The first power connection electrode PCE1 may be located on the ninth interlayer insulating layer INS9. The first power connection electrode PCE1 may be connected to the first power connection area PCAA1 of the semiconductor substrate SSUB through the contact terminal CTE, the first to eighth metal layers ML1, ML2, ML3, ML4, ML5, ML6, ML7, and ML8 and the first to eighth vias VA1, VA2, VA3, VA4, VA5, VA6, VA7, and VA8.

The first power connection electrode PCE1 may include first to fourth sub-power connection electrodes SPCE1, SPCE2, SPCE3, and SPCE4. The first to fourth sub-power connection electrodes SPCE1, SPCE2, SPCE3, and SPCE4 of the first power connection electrode PCE1 may be respectively substantially the same as the first to fourth reflective electrodes RL1, RL2, RL3, and RL4 of the reflective electrode layer RL described in conjunction with FIG. 8. That is, the first sub-power connection electrode SPCE1 may correspond to the first reflective electrode RL1, the second sub-power connection electrode SPCE2 may correspond to the second reflective electrode RL2, the third sub-power connection electrode SPCE3 may correspond to the third reflective electrode RL3, and the fourth sub-power connection electrode SPCE4 may correspond to the fourth reflective electrode RL4.

The second power connection electrode PCE2 may be located on the tenth interlayer insulating layer INS10. The second power connection electrode PCE2 may be connected to the first power connection electrode PCE1 through the tenth via VA10. The second power connection electrode PCE2 may include substantially the same material as the first electrode AND of the light-emitting element LE described in conjunction with FIG. 8. The second power connection electrode PCE2 may be partitioned by the pixel-defining layer PDL. The second electrode CAT of the light-emitting element LE may be connected to the second power connection electrode PCE2 that is exposed and not covered by the pixel-defining layer PDL.

The dam DAM may include a first sub-dam DM1 and a second sub-dam DM2. The first sub-dam DM1 and the second sub-dam DM2 may be substantially the same as the trench TRC. Each of the first sub-dam DM1 and the second sub-dam DM2 may penetrate the first pixel-defining layer PDL1, the second pixel-defining layer PDL2, and the third pixel-defining layer PDL3. The tenth interlayer insulating layer INS10 may be partially recessed at each of the first sub-dam DM1 and the second sub-dam DM2.

In each of the first sub-dam DM1 and the second sub-dam DM2, the first inorganic encapsulation layer TFE1 may be located on the bottom surface, the organic encapsulation layer TFE2 may be located on the first inorganic encapsulation layer TFE1, and the second inorganic encapsulation layer TFE3 may be located on the organic encapsulation layer TFE2. The organic encapsulation layer TFE2 may be located to fill a part of each of the first sub-dam DM1 and the second sub-dam DM2. Alternatively, the organic encapsulation layer TFE2 may be omitted on each of the first sub-dam DM1 and the second sub-dam DM2. That is, the first inorganic encapsulation layer TFE1 and the second inorganic encapsulation layer TFE3 may be located in each of the first sub-dam DM1 and the second sub-dam DM2.

The first sub-dam DM1 and the second sub-dam DM2 may reduce or prevent the likelihood of the organic encapsulation layer TFE2 flowing into the pad portion PDA and covering the pads PD. In a case where the organic encapsulation layer TFE2 covers the pads PD, the pads PD may not be electrically connected to the circuit board 300 (see FIG. 1).

The data driver 700 may include a plurality of data transistors DTR. Because each of the plurality of data transistors DTR may be formed substantially the same as the pixel transistors PTR described in conjunction with FIG. 8, a detailed description of the plurality of data transistors DTR will be omitted. In addition, because the contact terminal CTE, the first to eighth metal layers ML1, ML2, ML3, ML4, ML5, ML6, ML7, and ML8 and the first to eighth vias VA1, VA2, VA3, VA4, VA5, VA6, VA7, and VA8 electrically connected to the plurality of data transistors DTR are also substantially the same as those described in conjunction with FIG. 8, a description thereof will be omitted.

The sealing dam DAR may be located on the tenth interlayer insulating layer INS10. The sealing dam DAR may be located outside the dam DAM and the data driver 700 to surround them in the non-display area NDA. The sealing dam DAR may be located outside the encapsulation layer TFE and formed to have a height (e.g., predetermined height) to form a space in which the cover layer DCL is located. In one or more embodiments, the height of the sealing dam DAR may be greater than the depth of the dam DAM. Similar to the way the dam DAM serves to reduce or prevent the likelihood of the organic encapsulation layer TFE2 of the encapsulation layer TFE overflowing, the sealing dam DAR may reduce or prevent the likelihood of the material of the cover layer DCL overflowing. For example, the sealing dam DAR may be located to be spaced apart from the outer side surface of the pixel-defining layer PDL, and the cover layer DCL may be filled therebetween.

Each of the pads PD may include a pad metal layer PML. The pad metal layer PML may include a first sub-pad metal layer SPML1 and a second sub-pad metal layer SPML2. The first sub-pad metal layer SPML1 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. The second sub-pad metal layer SPML2 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the first sub-pad metal layer SPML1 may be made of aluminum (Al) and may have a thickness of approximately 12,000 Å. In addition, the second sub-pad metal layer SPML2 may be made of titanium nitride (TiN) and may have a thickness of approximately 600 Å. The thickness of the pad metal layer PML may be greater than the thickness of the reflective electrode layer RL.

A portion of the top surface of the pad metal layer PML of each pad PD may be exposed without being covered by the tenth interlayer insulating layer INS10. The first sub-pad metal layer SPML1 may be connected to a pad via PVA9 that penetrates the ninth interlayer insulating layer INS9 to be connected to the eighth metal layer ML8.

The encapsulation layer TFE and the cover layer DCL may also be located in a part of the non-display area NDA located on the lower side of the display area DAA. While the organic encapsulation layer TFE2 of the encapsulation layer TFE is located up to the inside of the dam DAM, the inorganic encapsulation layers TFE1 and TFE3 of the encapsulation layer TFE may be located up to the outside of the dam DAM to form an inorganic junction area. The cover layer DCL may be located up to the outside of the inorganic encapsulation layers TFE1 and TFE3 of the encapsulation layer TFE.

The cover layer DCL may be located beyond the display area DAA up to the non-display area NDA so that at least the display area DAA may be completely covered. The cover layer DCL may be located in the space surrounded by the sealing dam DAR, and the bottom surface thereof may be in contact with the encapsulation layer TFE and the pixel-defining layer PDL, and the side surface thereof may be in contact with the sealing dam DAR. The cover layer DCL may be located to surround the outer surfaces of the components located on the backplanes SBP and EBP to protect them and fill the stepped portion formed by the components. In one or more embodiments, the cover layer DCL may also be partially located in the non-display area NDA located on the upper side of the display area DAA.

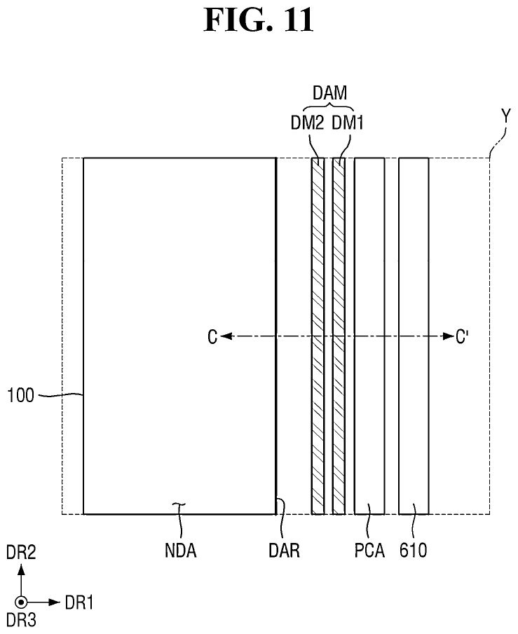

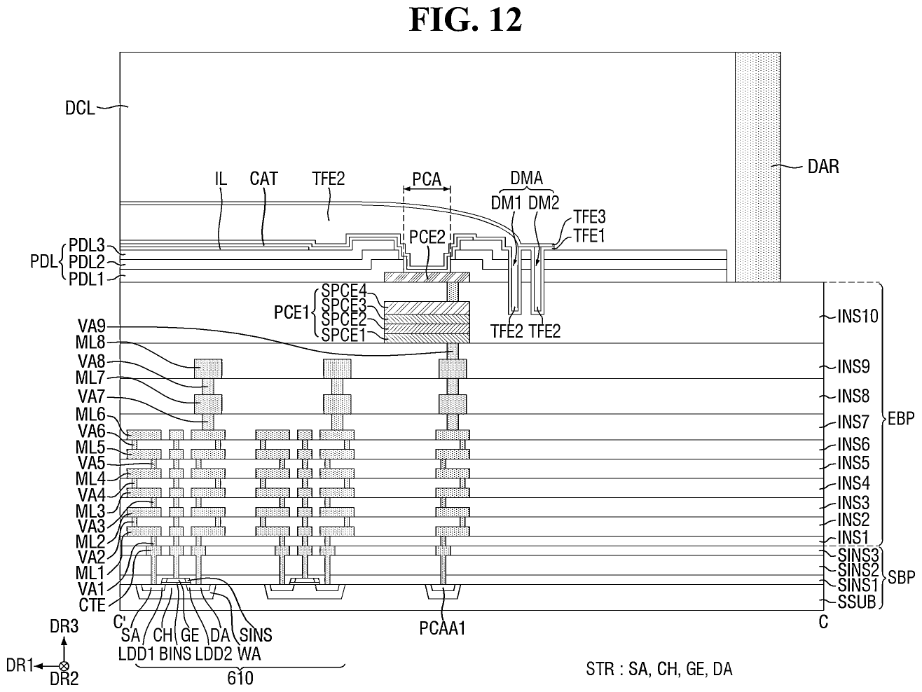

FIG. 11 is an enlarged view showing area Y of FIG. 4. FIG. 12 is a schematic cross-sectional view taken along the line C-C′ of FIG. 11.

The area Y of FIG. 4 may be an area located on the left side, which is one side of the display area DAA in the first direction DR1. FIGS. 11 and 12 illustrate the scan driver 610, the power connection portion PCA, the dam DAM, and the sealing dam DAR located on the left side of the display area DAA.

Referring to FIGS. 11 and 12, the scan driver 610, the power connection portion PCA, the dam DAM, and the sealing dam DAR may be sequentially located in the first direction DR1 on the left side of the display area DAA. However, the present disclosure is not limited thereto, and the power connection portion PCA may overlap the scan driver 610 in the thickness direction, and the dam DAM may overlap the scan driver 610 in the thickness direction.

The scan driver 610 may include a plurality of scan transistors STR. Because each of the plurality of scan transistors STR may be formed substantially the same as the pixel transistors PTR described in conjunction with FIG. 8, a detailed description of the plurality of scan transistors STR will be omitted. In addition, because the contact terminals CTE, the first to eighth metal layers ML1, ML2, ML3, ML4, ML5, ML6, ML7, and ML8 and the first to eighth vias VA1, VA2, VA3, VA4, VA5, VA6, VA7, and VA8 electrically connected to the plurality of scan transistors STR are also substantially the same as those described in conjunction with FIG. 8, a description thereof will be omitted.

Because the power connection portion PCA, the dam DAM, and the sealing dam DAR are substantially the same as those described in connection with FIGS. 9 and 10, detailed description thereof will be omitted.

In addition, because the area located on the second side of the display area DAA is substantially the same as those illustrated in FIGS. 11 and 12, except that the scan driver 610 replaces the emission driver 620, a description thereof will be omitted.

The encapsulation layer TFE and the cover layer DCL may also be located in a part of the non-display area NDA located on the left side of the display area DAA. While the organic encapsulation layer TFE2 of the encapsulation layer TFE is located up to the inside of the dam DAM, the inorganic encapsulation layers TFE1 and TFE3 of the encapsulation layer TFE may be located up to the outside of the dam DAM to form an inorganic junction area. The cover layer DCL may be located up to the outside of the inorganic encapsulation layers TFE1 and TFE3 of the encapsulation layer TFE. The cover layer DCL may be located beyond the display area DAA up to the non-display area NDA so that the display area DAA may be completely covered. In one or more embodiments, the cover layer DCL may also be partially located in the non-display area NDA located on the right side of the display area DAA.

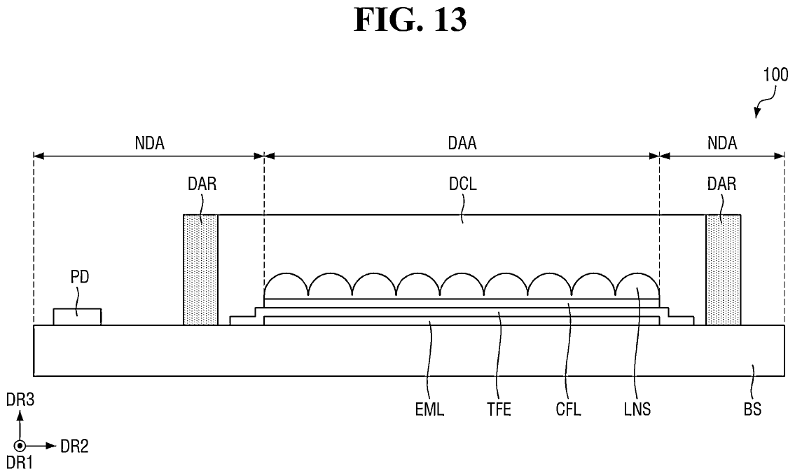

FIG. 13 is a schematic cross-sectional view of a display panel along a second direction according to one or more embodiments.

Referring to FIG. 13, the display device 10 may include the sealing dam DAR and the cover layer DCL located on a base substrate BS of the display panel 100. The light-emitting element layer EML, the encapsulation layer TFE, the color filter layer CFL, and the lens array layer LNS may be located on the base substrate BS of the display panel 100. The base substrate BS may include the semiconductor backplane SBP and the light-emitting element backplane EBP described above with reference to FIG. 8. Because a description thereof is the same as described above, a detailed description thereof will be omitted.

The sealing dam DAR may be located in the non-display area NDA to surround the components of the display panel 100 except for the pad PD. The sealing dam DAR may form an area in which the cover layer DCL for protecting the components located in the display panel 100 is located. The sealing dam DAR may have a height that is higher than that of the lens array layer LNS from the base substrate BS. In addition, the sealing dam DAR may be formed to be partially spaced apart from the encapsulation layer TFE so that the cover layer DCL can also surround the side surface of the encapsulation layer TFE. The encapsulation layer TFE may form an inorganic junction area at the outskirt of the dam DAM, and the sealing dam DAR may be formed in an area spaced apart from the inorganic junction area. In one or more embodiments, the sealing dam DAR may include a polymer resin.

The cover layer DCL may be located in the region surrounded by the sealing dam DAR to planarize the top surface of the display panel 100. The height of the cover layer DCL may be the same as the height of the sealing dam DAR, and the top surface of the cover layer DCL may be substantially on a level with the top surface of the sealing dam DAR. The cover layer DCL may cover at least the components located in the display area DAA, and may also be located in a part of the non-display area NDA to surround the components. The bottom surface of the cover layer DCL may be in contact with the lens array layer LNS, the encapsulation layer TFE, and the base substrate BS, and the side surface thereof may be in contact with the sealing dam DAR. The cover layer DCL may serve to protect the components located in the display panel 100 and, at the same time, planarize the top surface of the display panel 100 while filling the stepped portion formed by the components located on the base substrate BS. In one or more embodiments, the cover layer DCL may include a polymer resin of a transparent material.

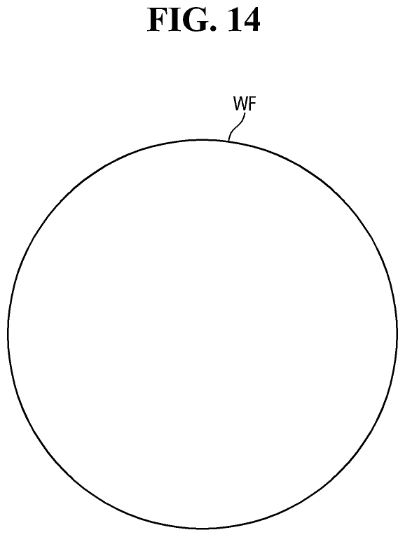

In the display device 10, as the display panel 100 includes the sealing dam DAR and the cover layer DCL made of the polymer resin, an additional hard cover member may be omitted. As will be described later, a fabrication process of the display device 10 may include forming a plurality of layers on a wafer substrate WF (see FIG. 14) and splitting the wafer substrate to form the display device 10. Because the display panel 100 of the display device 10 does not include an additional cover member, damage to the cover member during the splitting process, or damage to the display panel 100 caused thereby, may be reduced or prevented. Besides, because the process of forming the cover layer DCL including the polymer resin involves a process of smoothing the top surface, not a cutting or etching process that causes damage to the display panel 100, the surface quality of the display panel 100 can also be improved.

Hereinafter, a fabrication process of the display device 10 will be described with reference to other drawings.

FIGS. 14 to 24 are diagrams sequentially showing the fabrication process of a display device according to one or more embodiments.

A method of fabricating the display device 10 according to one or more embodiments may include an operation of forming the light-emitting element layer EML, the encapsulation layer TFE, the color filter layer CFL, and the lens array layer LNS for each unit area of the wafer substrate WF and forming the sealing dam DAR surrounding them, an operation of forming a resin layer in the region surrounded by the sealing dam DAR and planarizing the top surface of the resin layer, and an operation of forming the cover layer DCL by curing the resin layer. In the operation of forming the resin layer, the resin layer may be formed to spread in the space formed by the sealing dam DAR to thereby fill the space formed by the sealing dam DAR. Subsequently, the top surface of the resin layer may be planarized and cured to form the cover layer DCL having a smooth top surface.

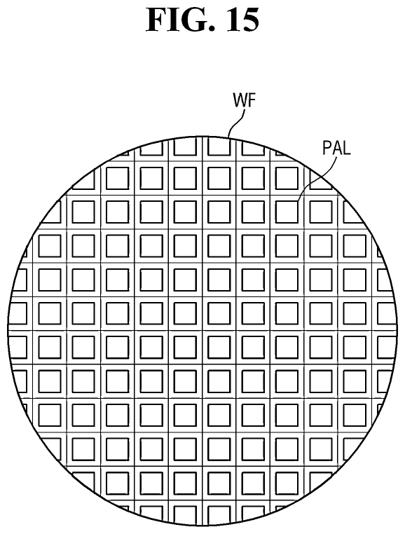

First, referring to FIGS. 14 and 15, the wafer substrate WF is prepared, and a preliminary display panel PAL is formed by forming the backplanes SBP and EBP, the light-emitting element layer EML, the encapsulation layer TFE, the color filter layer CFL, the lens array layer LNS, the pad PD, and so forth on the wafer substrate WF. The wafer substrate WF may be a silicon substrate, a germanium substrate, or a silicon-germanium substrate. The wafer substrate WF may be a substrate doped with the first type impurity, and may be a mother substrate of the semiconductor substrate SSUB of the display panel 100.

The plurality of transistors (e.g., pixel transistors PTR) are formed on one surface of the wafer substrate WF, and the backplanes SBP and EBP, the light-emitting element layer EML, the encapsulation layer TFE, the color filter layer CFL, the lens array layer LNS, and the like are then formed to form the preliminary display panel PAL. The process of forming the plurality of transistors on the wafer substrate WF may be a fine semiconductor process. After forming the backplanes SBP and EBP through the fine semiconductor process, the light-emitting element layer EML, the encapsulation layer TFE, the color filter layer CFL, and the lens array layer LNS are formed. The wafer substrate WF may include a plurality of unit areas, and the preliminary display panel PAL may be formed for each of the unit areas. The process of forming the light-emitting element layer EML, the encapsulation layer TFE, the color filter layer CFL, and the lens array layer LNS may be implemented by a typical process. The preliminary display panel PAL may constitute the display panel 100 as the sealing dam DAR and the cover layer DCL are formed in a process to be described later.

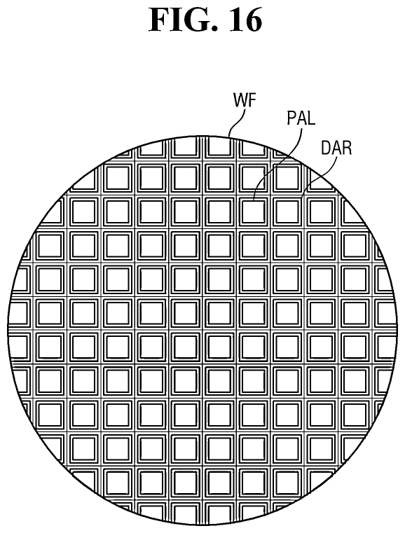

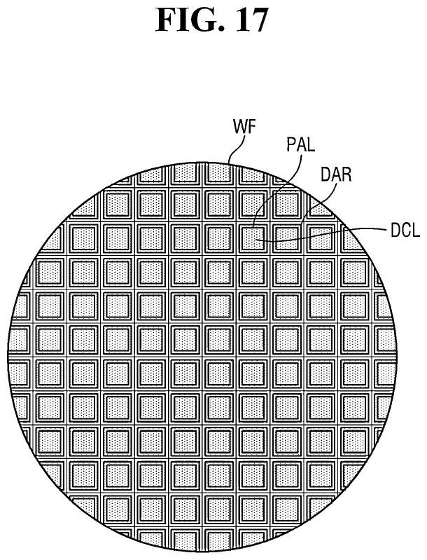

Next, referring to FIGS. 16 and 17, the sealing dam DAR and the cover layer DCL are formed in each of the unit areas of the wafer substrate WF. The process of forming the sealing dam DAR and the cover layer DCL may be a process of encapsulating the preliminary display panel PAL located on the wafer substrate WF. As described above, the cover layer DCL is formed to have a flat top surface while protecting the components located on the wafer substrate WF or the base substrate BS (see FIG. 13), thereby forming the top surface of the display panel 100. As one of the processes of forming the cover layer DCL, there may be performed a process of forming the sealing dam DAR on the preliminary display panel PAL, applying a resin forming the cover layer DCL into the space formed by the sealing dam DAR, and then flattening and curing the resin. The cover layer DCL may be formed for each area in which the preliminary display panel PAL is formed on the wafer substrate WF, and the display panel 100 may form the cover layer DCL protecting the preliminary display panel PAL without an additional cover member that is required to be split individually.

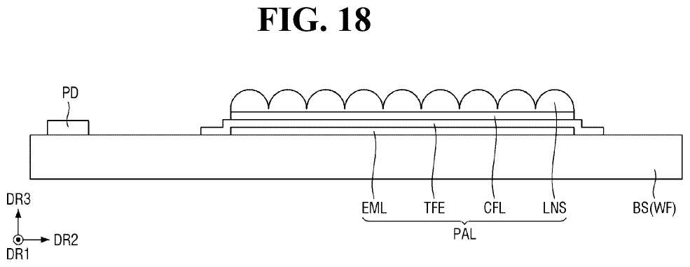

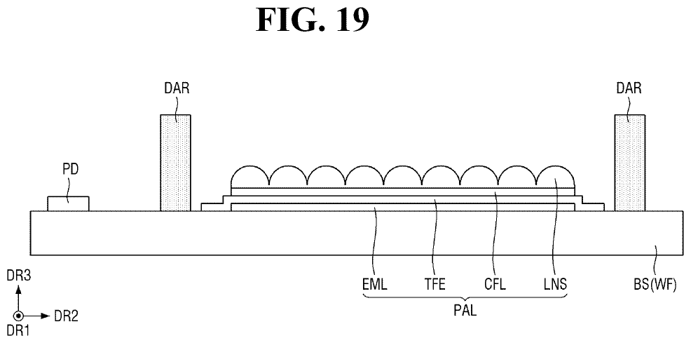

Referring to FIGS. 18 and 19, the preliminary display panel PAL is formed on the wafer substrate WF (or the base substrate BS), and the sealing dam DAR is formed to surround the preliminary display panel PAL. The pad PD may be formed to be spaced apart from the preliminary display panel PAL on the wafer substrate WF. The preliminary display panel PAL formed on the wafer substrate WF may include the light-emitting element layer EML, the encapsulation layer TFE, the color filter layer CFL, and the lens array layer LNS. However, the present disclosure is not limited thereto, and the preliminary display panel PAL may include all the components of the display panel 100 except for the base substrate BS and the pad PD. The components included in the display panel 100 are the components described above with reference to FIGS. 8 to 12, and may be understood as briefly illustrated in FIG. 18 for simplicity of description.

The sealing dam DAR may be formed in each unit area in which the preliminary display panel PAL and the pad PD are formed on the wafer substrate WF. The sealing dam DAR may be located to surround the portion of the unit area where the preliminary display panel PAL is located, except for the pad PD. In one or more embodiments, the sealing dam DAR may be formed of a polymer resin, and may be formed to have a height (e.g., predetermined height) from the wafer substrate WF. The height of the sealing dam DAR may be higher than the height of the preliminary display panel PAL.

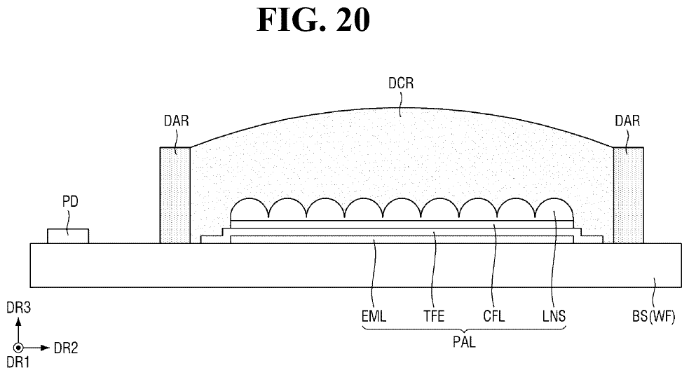

Subsequently, referring to FIG. 20, a resin layer DCR for forming the cover layer DCL is applied to the region surrounded by the sealing dam DAR on the preliminary display panel PAL. The resin layer DCR may include a polymer resin to cover the preliminary display panel PAL and fill a space between the preliminary display panel PAL and the sealing dam DAR. Because the resin layer DCR is a material having fluidity before it is cured, it may be applied to protrude higher than the top surface of the sealing dam DAR due to a difference in material with respect to the sealing dam DAR. However, the present disclosure is not limited thereto. The resin layer DCR may be concavely recessed at a portion in contact with the sealing dam DAR. However, the overall shape or thickness of the cover layer DCL may be controlled by adjusting the application amount of the resin layer DCR. The planar area of the cover layer DCL may be equal to that of the region surrounded by the sealing dam DAR, and the thickness of the cover layer DCL may be substantially the same as the height of the sealing dam DAR. The application amount of the resin layer DCR may be adjusted according to the area and the height of the sealing dam DAR, and may be adjusted to an amount sufficient to fill the space between the preliminary display panel PAL and the sealing dam DAR.

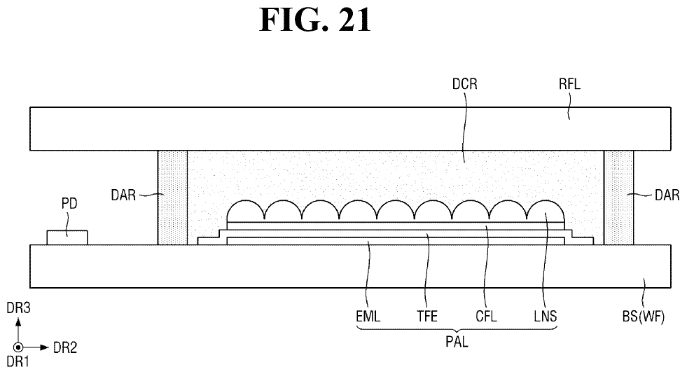

Subsequently, referring to FIG. 21, the top surface of the resin layer DCR may be planarized by attaching a release film RFL onto the resin layer DCR and the sealing dam DAR. As the resin layer DCR includes the material having fluidity, it is easy to fill the space formed by the sealing dam DAR. However, when the resin layer DCR is cured as it is, the top surface of the display panel 100 may not be flat. In consideration of this, the resin layer DCR may be planarized by attaching the release film RFL onto the resin layer DCR and the sealing dam DAR. The present process may be performed by bonding in a vacuum chamber so that the resin layer DCR may be planarized while filling the space formed by the sealing dam DAR, the release film RFL, and the wafer substrate WF.

In some embodiments, one surface of the release film RFL in contact with the resin layer DCR may be surface-treated or coated. The release film RFL may have a surface property that guides the resin layer DCR to be well spread so that the resin layer DCR may sufficiently fill the region surrounded by the sealing dam DAR in the process of planarizing the resin layer DCR. The surface of the release film RFL may be treated to be hydrophilic or hydrophobic according to the physical properties of the resin layer DCR.

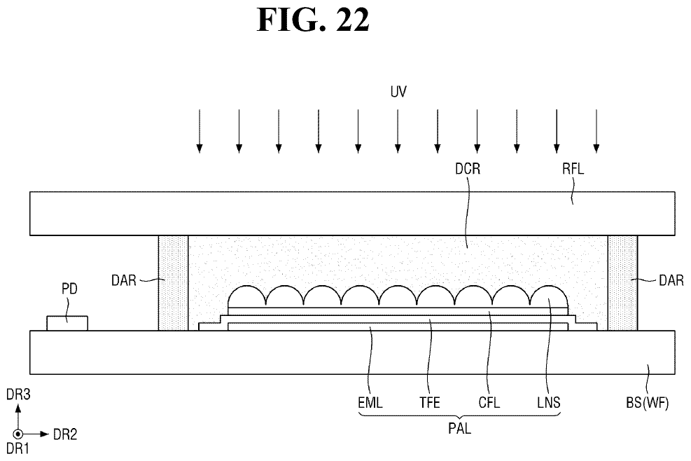

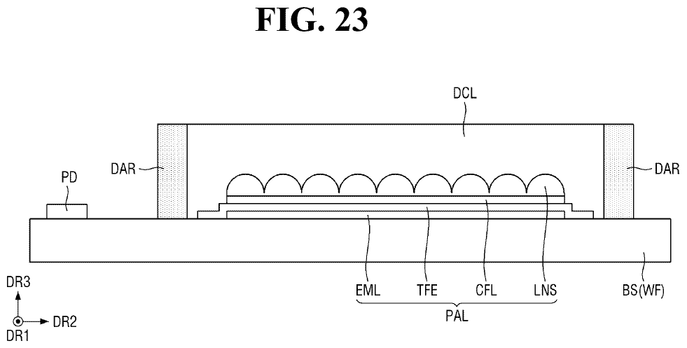

Subsequently, referring to FIGS. 22 and 23, by irradiating ultraviolet light (UV) to the resin layer DCR or heat-treating the resin layer DCR, the resin layer DCR is cured to form the cover layer DCL, and the release film RFL is removed. The release film RFL may be completely removed so that the cover layer DCL and the sealing dam DAR may be left on the display panel 100. Because the resin layer DCR is cured in the state where the release film RFL is attached, it is cured in the state where the space formed by the sealing dam DAR is completely filled, and the top surface thereof may be planarized. In addition, because the space formed by the sealing dam DAR can be completely filled by adjusting the application amount of the resin layer DCR, the portion where the cover layer DCL and the sealing dam DAR contact each other, and the space between the preliminary display panel PAL and the sealing dam DAR can all be filled with the cover layer DCL. In the display panel 100, the cover layer DCL located on the uppermost layer thereof may have the smooth top surface, and there may exist no space between the sealing dam DAR and the cover layer DCL.

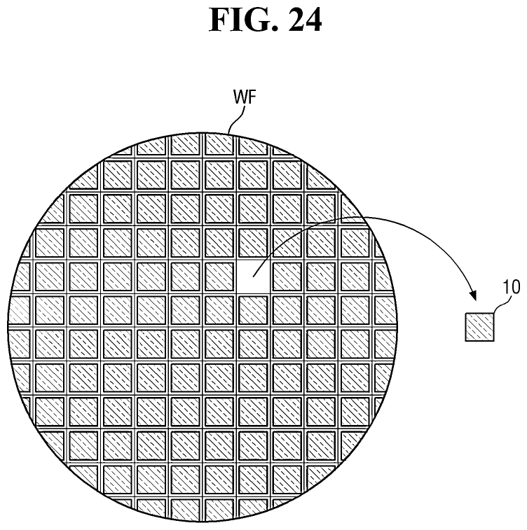

Subsequently, referring to FIG. 24, the wafer substrate WF is split to form the display panel 100, and the circuit board 300 (see FIG. 1) is attached to the display panel 100 to fabricate the display device 10. The wafer substrate WF may be split for each unit area in which one preliminary display panel PAL and the cover layer DCL are formed. The fabrication process of the display device 10 may be performed to fabricate several display panels 100 on the single wafer substrate WF. Accordingly, the fabricating yield of the display device 10 may be excellent.

In addition, as the cover layer DCL is formed to correspond to each of the preliminary display panels PAL in the process of splitting the wafer substrate WF, there involves no process of splitting an additional cover member covering the preliminary display panel PAL, which has the advantage that the display panel 100 is free from the risk of breakage and damage.

In the method of fabricating the display device 10 according to one or more embodiments, the cover layer DCL to be located on the uppermost layer of the display panel 100 may be formed using the polymer resin such that it has the smooth top surface while protecting the components included in the display panel 100. Accordingly, the display panel 100 may have very excellent surface quality, and when the light emitted from the light-emitting element layer EML is outputted in an upward direction from the display panel 100, it is possible to reduce or prevent deterioration of display quality due to the light being scattered or refracted on the surface of the cover layer DCL.

Hereinafter, various embodiments of the display device 10 will be described with reference to other drawings.

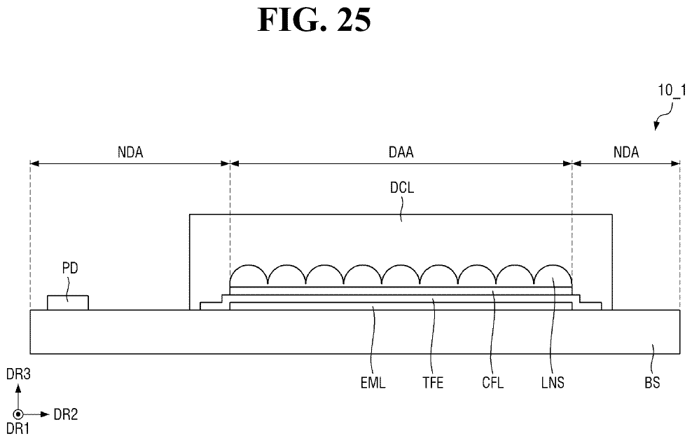

FIG. 25 is a schematic cross-sectional view of a display panel of a display device along a second direction according to one or more other embodiments.

Referring to FIG. 25, in a display device 10_1 according to one or more embodiments, the sealing dam DAR located in the display panel 100 may be omitted. In the display device 10_1, the cover layer DCL located on the lens array layer LNS of the display panel 100 is formed to completely surround the light-emitting element layer EML, the encapsulation layer TFE, the color filter layer CFL, and the lens array layer LNS, and may have smooth top and side surfaces.

In the display panel 100 of FIG. 13, the sealing dam DAR is a member for forming a space in which the cover layer DCL is to be located, and if the shape of the cover layer DCL can be controlled and the top surface thereof can be planarized in the process of forming the cover layer DCL, the sealing dam DAR may be omitted. In the fabrication process of FIGS. 18 to 23, the shape of the cover layer DCL is controlled and the top surface thereof is planarized by using the sealing dam DAR and the release film RFL. However, the fabricating method of the display device 10_1 is not necessarily limited thereto. The display device 10_1 may be fabricated through a fabrication process enabling the cover layer DCL to have a flat top surface even when the sealing dam DAR is omitted.

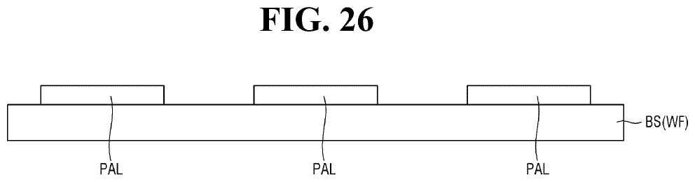

FIGS. 26 to 31 are cross-sectional views illustrating a part of a fabrication process of a display device according to one or more other embodiments.

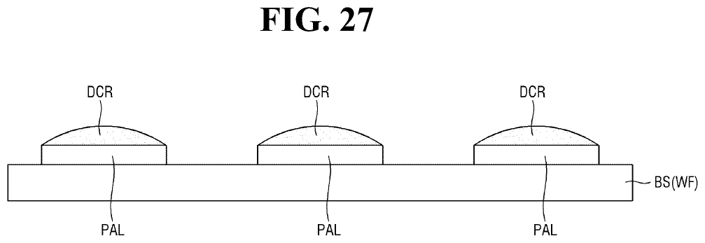

Referring to FIGS. 26 to 31, in the fabrication process of the display device 10_1 according to one or more embodiments, the resin layer DCR may be formed to have a controlled shape and flat top and side surfaces by using a mold MLD. For example, as shown in FIGS. 26 and 27, after the multiple preliminary display panels PAL are formed on the wafer substrate WF, the resin layer DCR is applied thereon. The resin layer DCR is applied to correspond to each of the preliminary display panels PAL. Because there is no sealing dam DAR, it may overflow from the preliminary display panel PAL over time.

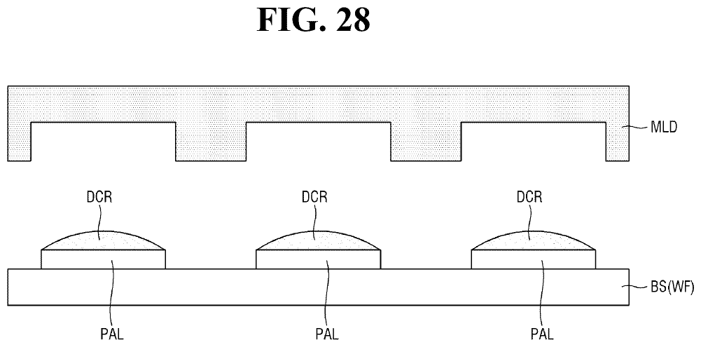

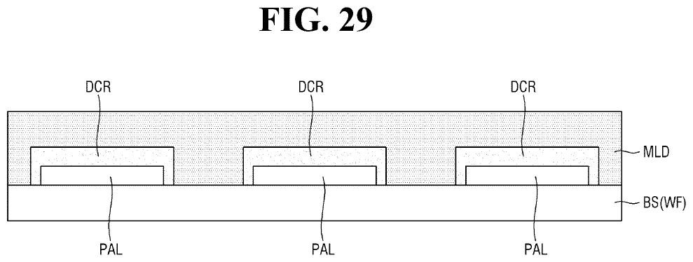

Subsequently, as shown in FIGS. 28 and 29, the mold MLD whose bottom surface is partially recessed to correspond to each unit area in which the preliminary display panel PAL is located on the wafer substrate WF is provided, and the mold MLD is brought into contact with the wafer substrate WF so that the recessed portion of the mold MLD surrounds the resin layer DCR and the preliminary display panel PAL. The mold MLD may serve a role similar to that of the sealing dam DAR. When the mold MLD and the wafer substrate WF are brought into contact with each other, the resin layer DCR may completely surround the preliminary display panel PAL and completely fill the recessed portion of the mold MLD. The resin layer DCR may fill the space formed by the mold MLD and the wafer substrate WF. In FIG. 27, the application amount of the resin layer DCR may be adjusted in consideration of the volume of the recessed portion of the mold MLD as well as the shape and the thickness of the cover layer DCL, and, for example, may be adjusted to an amount sufficient to completely fill the recessed portion of the mold MLD when the mold MLD and the wafer substrate WF come into contact with each other.

In one or more embodiments, the recessed portion of the mold MLD may have a depth greater than the thickness of the preliminary display panel PAL, and may have, in plan view, an area greater than the area of the preliminary display panel PAL. The resin layer DCR filling the recessed portion of the mold MLD may naturally completely surround the top surface and the side surface of the preliminary display panel PAL. The resin layer DCR may be formed to completely protect the preliminary display panel PAL as the top and side surfaces thereof are planarized by the mold MLD.

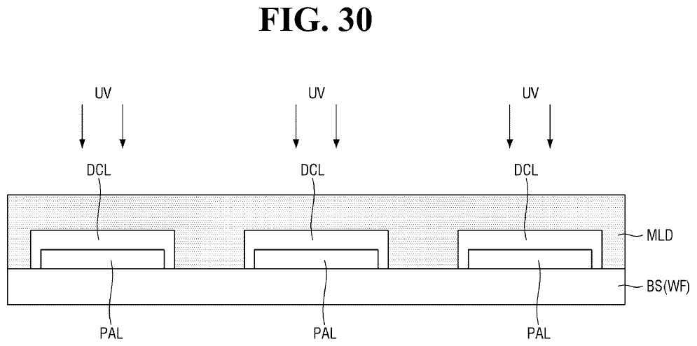

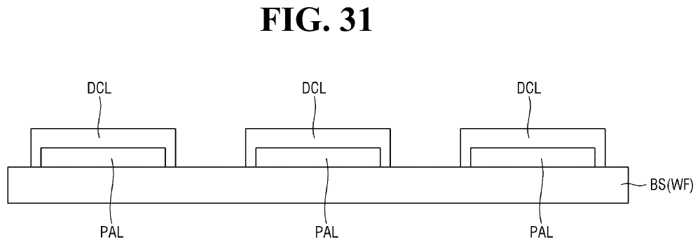

Subsequently, as shown in FIGS. 30 and 31, by irradiating UV to the resin layer DCR or heat-treating the resin layer DCR, the resin layer DCR is cured to form the cover layer DCL, and the mold MLD is removed. The mold MLD may be made of a transparent material so that it may transmit the UV. As an example, the mold MLD may be formed of transparent glass. The multiple preliminary display panels PAL and the cover layer DCL located to correspond to each of the preliminary display panels PAL may remain on the wafer substrate WF. The cover layer DCL may be given smooth top and side surfaces even when there is no sealing dam DAR, and may be formed to completely surround each of the preliminary display panels PAL.

In one or more embodiments, the display panel 100 may be formed by splitting the wafer substrate WF into multiple pieces, and the display device 10_1 may be fabricated by attaching the circuit board 300 (see FIG. 1) to the display panel 100. In the display device 10_1 according to one or more embodiments, even if the sealing dam DAR is not located on the display panel 100, it is still possible to form the cover layer DCL with smooth top and side surfaces through the planarization process of the resin layer DCR using the mold MLD during the fabrication process.

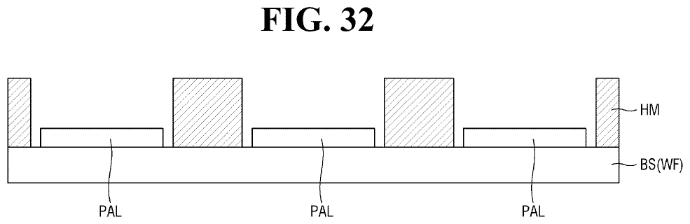

FIGS. 32 to 36 are cross-sectional views illustrating a part of a fabrication process of a display device according to still one or more other embodiments.

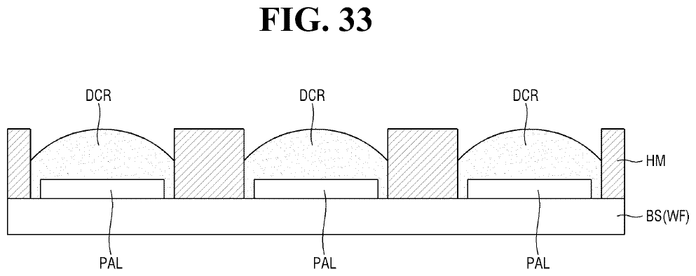

Referring to FIGS. 32 to 36, in a method of fabricating the display device 10, a planarization process of the resin layer DCR may be performed by using a hard mask HM and a soft mold SMD. As shown in FIGS. 32 and 33, after forming multiple preliminary display panels PAL on the wafer substrate WF, the hard mask HM including holes exposing the preliminary display panels PAL respectively is placed on the wafer substrate WF. The hard mask HM may be directly located on the wafer substrate WF, but is not limited thereto. The hard mask HM may be placed on the wafer substrate WF using a jig. However, the bottom surface of the hard mask HM may be in contact with the top surface of the wafer substrate WF so that the resin layer DCR applied on the preliminary display panel PAL does not flow.

In one or more embodiments, the hard mask HM may be made of a metal material. The hard mask HM may have a hard material to control the shape of the resin layer DCR applied on the preliminary display panel PAL.

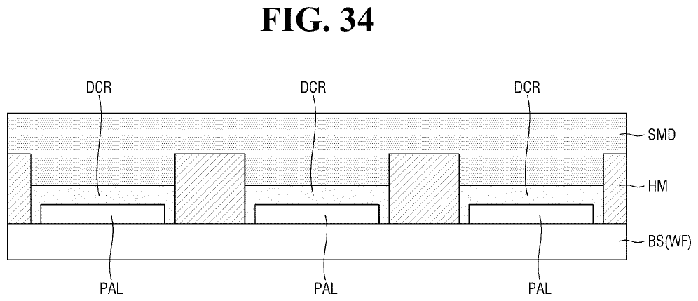

Subsequently, as shown in FIGS. 33 and 34, the soft mold SMD having protrusions formed to respectively correspond to the holes of the hard mask HM is placed on the hard mask HM. The soft mold SMD may be located to be in direct contact with the hard mask HM, and the hole of the hard mask HM and the protrusion of the soft mold SMD may correspond to the unit area in which the preliminary display panel PAL is located. The hole of the hard mask HM and the protrusion of the soft mold SMD may guide the resin layer DCR to completely fill the space between the hard mask HM, the soft mold SMD and the wafer substrate WF while completely surrounding the preliminary display panel PAL. In one or more embodiments, the soft mold SMD may be made of a transparent flexible material. As an example, the soft mold SMD may be formed of a silicon elastic body, such as PDMS. The hard mask HM may be made of a hard material, the soft mold SMD may be made of a flexible material, and the resin layer DCR may completely fill the space formed by the hard mask HM, the soft mold SMD, and the wafer substrate WF.

In addition, the shape of the cover layer DCL may be controlled by adjusting the planar areas, the heights, and the thicknesses of the hole of the hard mask HM and the protrusion of the soft mold SMD. In FIG. 32, the application amount of the resin layer DCR may be adjusted in consideration of the hole of the hard mask HM, the protrusion of the soft mold SMD, the volume of the space formed by the wafer substrate WF, the shape and the thickness of the cover layer DCL, and so forth. For example, the application amount of the resin layer DCR may be adjusted to an amount sufficient to completely fill the space formed by the hard mask HM and the soft mold SMD when they come into contact with each other.

In one or more embodiments, the thickness of the hard mask HM may be greater than the thickness of the preliminary display panel PAL, and the thickness of the protrusion of the soft mold SMD may be less than the thickness of the hard mask HM. The resin layer DCR filling the space between the hard mask HM and the soft mold SMD may have a sufficient thickness while completely surrounding the preliminary display panel PAL. In addition, the resin layer DCR may have smooth top and side surfaces in contact with the soft mold SMD and the hard mask HM, respectively.

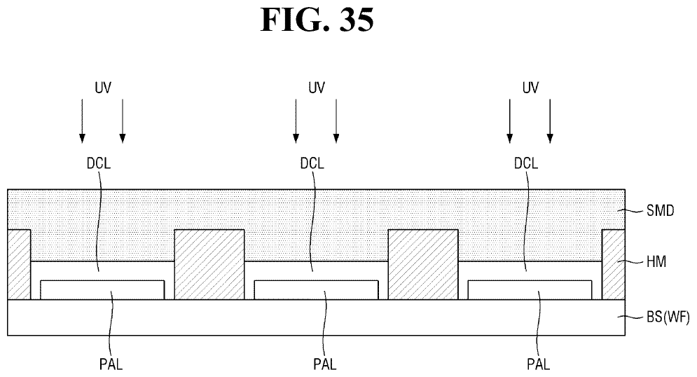

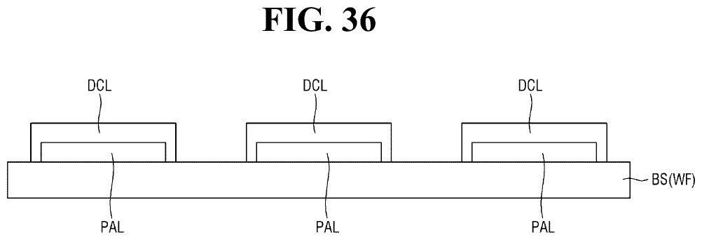

Subsequently, as shown in FIGS. 35 and 36, by irradiating UV to the resin layer DCR or heat-treating the resin layer DCR, the resin layer DCR is cured to form the cover layer DCL, and the soft mold SMD and the hard mask HM are removed. The multiple preliminary display panels PAL and the cover layer DCL located to correspond to each of them may remain on the wafer substrate WF. The cover layer DCL may be given smooth top and side surfaces even when there is no sealing dam DAR, and may be formed to completely surround each of the preliminary display panels PAL. Subsequently, in one or more embodiments, the display panel 100 may be formed by splitting the wafer substrate WF into multiple pieces, and the display device 10 may be fabricated by attaching the circuit board 300 (see FIG. 1) to the display panel 100.

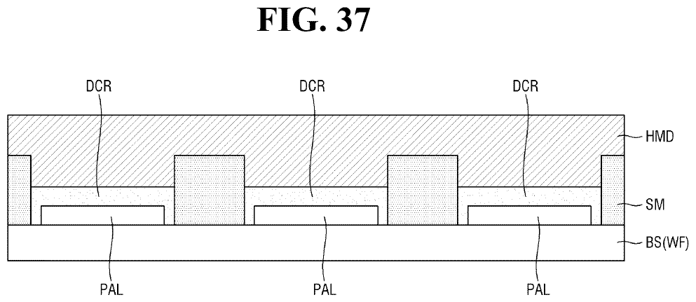

FIG. 37 is a cross-sectional view illustrating one operation in a fabrication process of a display device according to yet one or more other embodiments.

Referring to FIG. 37, in a method of fabricating the display device 10, a planarization process of the resin layer DCR may be performed by using the soft mask SM and the hard mold HMD. The one or more embodiments corresponding to FIG. 37 may be different from the one or more embodiments corresponding to FIG. 34 in that the materials of the soft mask SM and the hard mold HMD are reversed. Because the other descriptions are the same as those described above, a detailed description thereof will be omitted here.

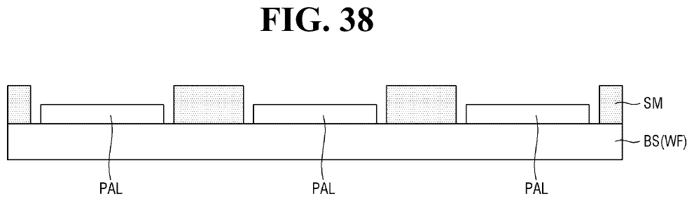

FIGS. 38 to 41 are cross-sectional views illustrating a part of a fabrication process of a display device according to still one or more other embodiments.

Referring to FIGS. 38 to 41, in a method of fabricating the display device 10, a planarization process of the resin layer DCR may be performed by using the soft mask SM and the release film RFL. The above differs from the one or more embodiments corresponding to FIGS. 26 to 31 in that the height of the soft mask SM is set to be equal to the height or thickness of the cover layer DCL and the release film RFL having no protruding or recessed portion is used as a top surface planarization member for the cover layer DCL.

As shown in FIG. 38, the soft mask SM, which includes holes formed to respectively correspond to the unit areas in which the preliminary display panels PAL are located, is placed on the wafer substrate WF. The soft mask SM may include a flexible silicon material, such as PDMS. In one or more embodiments, the planar area of the hole and the thickness of the soft mask SM may be the same as the planar area and the thickness of the cover layer DCL. In the fabrication process, the shape of the cover layer DCL may be controlled by adjusting the thickness of the soft mask SM and the area of the hole.

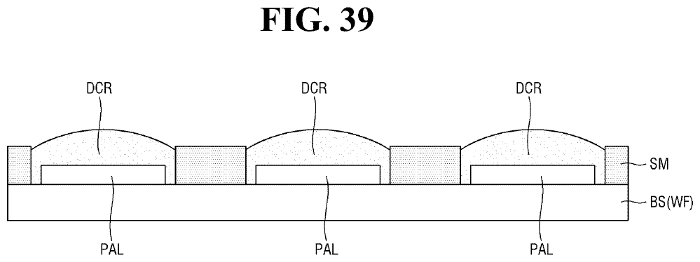

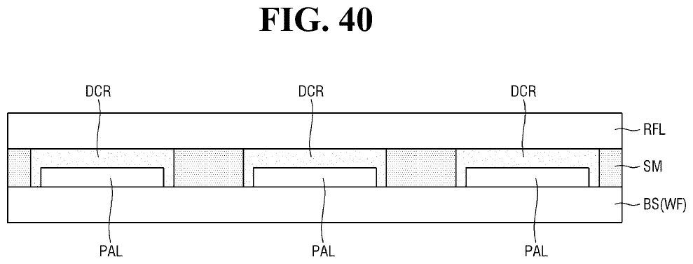

Then, as shown in FIGS. 39 and 40, the resin layer DCR is applied on the preliminary display panel PAL, and the release film RFL is located on the soft mask SM to planarize the top surface of the resin layer DCR. The resin layer DCR may completely surround the preliminary display panel PAL while filling the space formed by the soft mask SM, the release film RFL, and the wafer substrate WF. In addition, the top and side surfaces of the resin layer DCR may be planarized as they come into contact with the soft mask SM and the release film RFL. The release film RFL may be formed to have a flat bottom surface, and the thickness of the soft mask SM and the thickness of the resin layer DCR may be controlled to be the same.

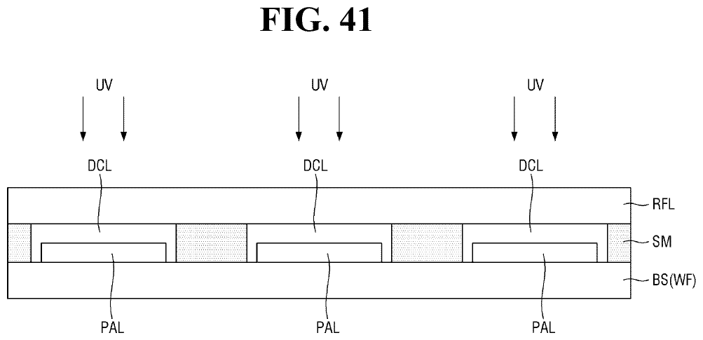

Subsequently, as shown in FIG. 41, by irradiating UV to the resin layer DCR or heat-treating the resin layer DCR, the resin layer DCR is cured to form the cover layer DCL. The release film RFL may be made of a transparent material so that it may transmit UV. As an example, the release film RFL may be formed of transparent glass. Subsequently, when the soft mask SM and the release film RFL are removed, the multiple preliminary display panels PAL and the cover layer DCL located to correspond to each of them may remain on the wafer substrate WF. The cover layer DCL may be given smooth top and side surfaces even when there is no sealing dam DAR, and may be formed to completely surround each of the preliminary display panels PAL.

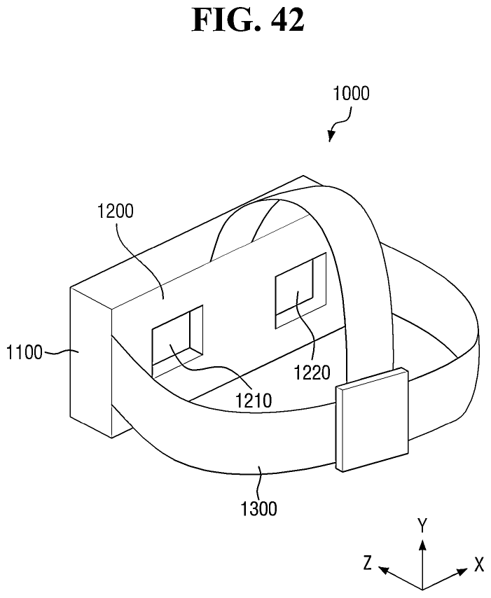

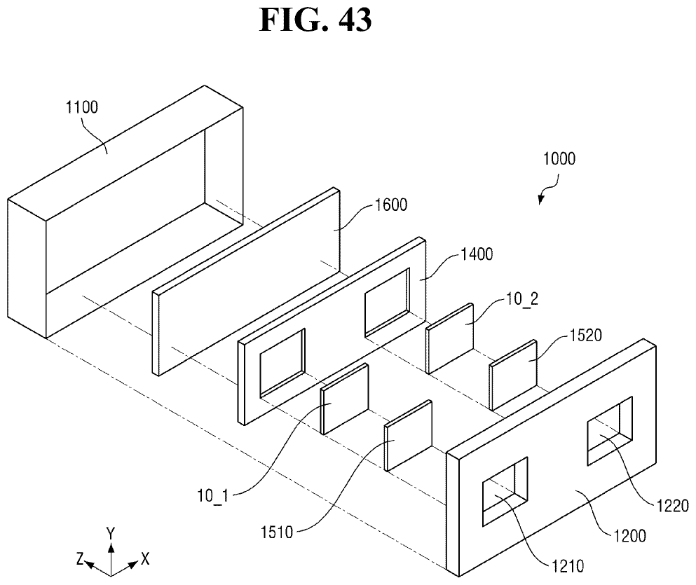

FIG. 42 is a perspective view illustrating a head mounted display device according to one or more embodiments. FIG. 43 is an exploded perspective view showing an example of the head mounted display device of FIG. 42.

Referring to FIGS. 42 and 43, a head mounted display device 1000 according to one or more embodiments includes a first display device 10_1, a second display device 10_2, a display device storage 1100, a storage cover 1200, a first eyepiece 1210, a second eyepiece 1220, a head mounted band 1300, a middle frame 1400, a first optical member 1510, a second optical member 1520, a control circuit board 1600, and a connector.

The first display device 10_1 provides an image to a user's left eye, and the second display device 10_2 provides an image to a user's right eye. Because each of the first display device 10_1 and the second display device 10_2 is substantially the same as the display device 10 described in conjunction with FIG. 1, the description of the first display device 10_1 and the second display device 10_2 will be omitted.

The first optical member 1510 may be located between the first display device 10_1 and the first eyepiece 1210. The second optical member 1520 may be located between the second display device 10_2 and the second eyepiece 1220. Each of the first optical member 1510 and the second optical member 1520 may include at least one convex lens.

The middle frame 1400 may be located between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be located between the middle frame 1400 and the display device storage 1100. The control circuit board 1600 may be connected to the first display device 10_1 and the second display device 10_2 through the connector. The control circuit board 1600 may convert an image source inputted from the outside into the digital video data DATA (see FIG. 2), and may transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. Alternatively, the control circuit board 1600 may transmit the same digital video data DATA to the first display device 10_1 and the second display device 10_2.

The display device storage 1100 serves to accommodate the first display device 10_1, the second display device 10_2, the middle frame 1400, the first optical member 1510, the second optical member 1520, the control circuit board 1600, and the connector. The storage cover 1200 is located to cover one open surface of the display device storage 1100. The storage cover 1200 may include the first eyepiece 1210 at which the user's left eye is located and the second eyepiece 1220 at which the user's right eye is located. FIGS. 42 and 43 illustrate that the first eyepiece 1210 and the second eyepiece 1220 are located separately, but the present disclosure is not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Accordingly, the user may view the image of the first display device 10_1 magnified as a virtual image by the first optical member 1510 through the first eyepiece 1210, and may view the image of the second display device 10_2 magnified as a virtual image by the second optical member 1520 through the second eyepiece 1220.

The head mounted band 1300 serves to secure the display device storage 1100 to the user's head such that the first eyepiece 1210 and the second eyepiece 1220 of the storage cover 1200 remain located on the user's left and right eyes, respectively. When the display device storage 1100 is implemented to be lightweight and compact, the head mounted display device 1000 may be provided with, as shown in FIG. 42, an eyeglass frame instead of the head mounted band 1300.

In addition, the head mounted display device 1000 may further include a battery for supplying power, an external memory slot for accommodating an external memory, and an external connection port and wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

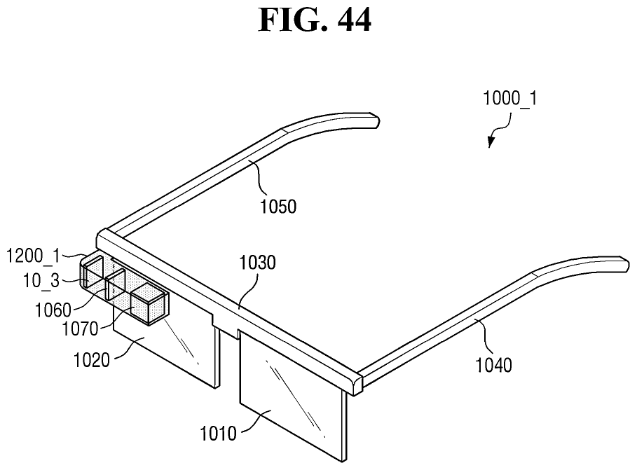

FIG. 44 is a perspective view illustrating a head mounted display device according to one or more embodiments.

Referring to FIG. 44, a head mounted display device 1000_1 according to one or more embodiments may be an eyeglasses-type display device in which a display device storage 1200_1 is implemented in a lightweight and compact manner. The head mounted display device 1000_1 according to one or more embodiments may include a display device 10_3, a left eye lens 1010, a right eye lens 1020, a support frame 1030, temples 1040 and 1050, an optical member 1060, an optical path changing member 1070, and the display device storage 1200_1.

The display device storage 1200_1 may include the display device 10_3, the optical member 1060, and the optical path changing member 1070. An image displayed on the display device 10_3 may be magnified by the optical member 1060, and the optical path may be changed by the optical path changing member 1070 to provide the image to the user's right eye through the right eye lens 1020. As a result, the user may view an augmented reality image, through the right eye, in which a virtual image displayed on the display device 10_3 and a real image seen through the right eye lens 1020 are combined.

FIG. 44 illustrates that the display device storage 1200_1 is located at the right end of the support frame 1030, but the present disclosure is not limited thereto. For example, the display device storage 1200_1 may be located on the left end of the support frame 1030, and in this case, the image of the display device 10_3 may be provided to the user's left eye. Alternatively, the display device storage 1200_1 may be located on both the left and right ends of the support frame 1030, and in this case, the user may view the image displayed on the display device 10_3 through both the left and right eyes.

In concluding the detailed description, those skilled in the art will appreciate that many variations and modifications can be made to the embodiments without substantially departing from the aspects of the present disclosure. Therefore, the disclosed embodiments of the present disclosure are used in a generic and descriptive sense only and not for purposes of limitation.

What is claimed is:

1. A display device comprising:
a semiconductor substrate comprising a display area comprising transistors, and a non-display area around the display area in plan view;
a light-emitting element layer above the semiconductor substrate, and comprising light-emitting elements in the display area;
an encapsulation layer above the light-emitting element layer;
a color filter layer above the encapsulation layer, and comprising color filters respectively overlapping the light-emitting elements;
a lens array layer above the color filter layer, and comprising lenses in the display area; and
a cover layer above the lens array layer, having flat top and side surfaces, and surrounding the light-emitting element layer, the encapsulation layer, the color filter layer, and the lens array layer in plan view.

2. The display device of claim 1, further comprising pads in the non-display area,
wherein the cover layer does not overlap the pads.

3. The display device of claim 1, further comprising a sealing dam in the non-display area, and surrounding the cover layer in plan view,
wherein a planar area of a region surrounded by the sealing dam is equal to a planar area of the cover layer.

4. The display device of claim 3, wherein the sealing dam contacts the side surface of the cover layer, and
wherein a height of the sealing dam is equal to a height of the cover layer.

5. The display device of claim 3, further comprising a gate driver and a scan driver in the non-display area,
wherein the sealing dam surrounds the gate driver and the scan driver in plan view, and
wherein the cover layer overlaps the gate driver and the scan driver.

6. The display device of claim 3, wherein the sealing dam and the cover layer comprise a polymer resin.

7. The display device of claim 1, wherein the encapsulation layer comprises a first inorganic encapsulation layer, an organic encapsulation layer above the first inorganic encapsulation layer, and a second inorganic encapsulation layer above the organic encapsulation layer, and
wherein the cover layer overlaps an inorganic junction area where the first inorganic encapsulation layer and the second inorganic encapsulation layer contact each other in the non-display area.

8. The display device of claim 1, wherein the cover layer directly contacts the lenses of the lens array layer.

9. A method of fabricating a display device, the method comprising:
preparing a wafer substrate comprising transistors, and having unit areas defined therein;
forming light-emitting element layers comprising light-emitting elements in the unit areas of the wafer substrate;
forming an encapsulation layer above the light-emitting element layer;
forming a color filter layer above the encapsulation layer;
forming a lens array layer above the color filter layer;
applying a resin layer on the lens array layer;
planarizing a top surface of the resin layer;
curing the resin layer to form a cover layer surrounding the light-emitting element layer, the encapsulation layer, the color filter layer, and the lens array layer in plan view; and
splitting the wafer substrate into the unit areas to form display panels.

10. The method of claim 9, further comprising forming a sealing dam surrounding the light-emitting element layer for the unit areas of the wafer substrate,
wherein the resin layer is applied within a region surrounding the sealing dam.

11. The method of claim 10, wherein the planarizing of the top surface of the resin layer comprises attaching a release film having a flat bottom surface onto the sealing dam and the resin layer, and
wherein the resin layer fills a space defined by the sealing dam and the release film.

12. The method of claim 11, wherein, in the attaching of the release film, the resin layer surrounds the light-emitting element layer, the encapsulation layer, the color filter layer, and the lens array layer within the unit area of the wafer substrate in plan view.

13. The method of claim 10, wherein the cover layer comprises a flat top surface and a side surface directly contacting the sealing dam.

14. The method of claim 9, wherein the planarizing of the top surface of the resin layer comprises placing a mold comprising a recessed portion corresponding to the unit area where the light-emitting element layer is located, and
wherein the resin layer fills a space defined by the wafer substrate and the mold.

15. The method of claim 14, wherein a depth of the recessed portion of the mold is equal to a thickness of the cover layer.

16. The method of claim 14, wherein the mold comprises a transparent material.

17. The method of claim 9, further comprising placing a mask comprising holes respectively corresponding to the unit areas on the wafer substrate,
wherein the planarizing of the top surface of the resin layer comprises placing a mold on the mask, and
wherein the resin layer fills a space defined by the wafer substrate, the mask, and the mold.

18. The method of claim 17, wherein the resin layer surrounds the light-emitting element layer, the encapsulation layer, the color filter layer, and the lens array layer.

19. The method of claim 17, wherein a thickness of the mask is greater than a height of the lens array layer,
wherein the mold has a bottom surface having protrusions respectively corresponding to the holes of the mask, and
wherein a thickness of the protrusion of the mold is less than the thickness of the mask.

20. The method of claim 17, wherein the mask comprises a metal material, and
wherein the mold comprises a flexible material.

21. The method of claim 17, wherein the mask comprises a flexible material, and
wherein the mold is a transparent hard mold.

22. The method of claim 9, further comprising placing a soft mask defining holes respectively corresponding to the unit areas on the wafer substrate,
wherein the planarizing of the top surface of the resin layer comprises placing a release film having a flat bottom surface on the soft mask, and
wherein the resin layer fills a space defined by the wafer substrate, the soft mask, and the release film.

23. The method of claim 22, wherein a thickness of the soft mask is equal to a thickness of the cover layer.

24. A head mounted display device comprising:
a frame mounted on a user's body, and corresponding to left and right eyes;
display devices in the frame; and
an eyepiece above the display devices,
wherein the display devices comprise:
a semiconductor substrate comprising a display area comprising transistors, and a non-display area around the display area in plan view;
a light-emitting element layer above the semiconductor substrate, and comprising light-emitting elements in the display area;
an encapsulation layer above the light-emitting element layer;
a color filter layer above the encapsulation layer, and comprising color filters respectively overlapping the light-emitting elements;
a lens array layer above the color filter layer, and comprising lenses in the display area; and
a cover layer above the lens array layer, having flat top and side surfaces, and surrounding the light-emitting element layer, the encapsulation layer, the color filter layer, and the lens array layer in plan view.

25. The head mounted display device of claim 24, wherein the display device further comprises a sealing dam in the non-display area, and surrounding the cover layer in plan view, and
wherein the sealing dam directly contacts the side surface of the cover layer.
